(19) United States
(12) Patent Application Publication
(10) Pub. No.: US 2024/0313189 A1
(43) Pub. Date: Sep. 19, 2024

(54) DISPLAY APPARATUS

(71) Applicant: SAMSUNG ELECTRONICS CO., LTD., Suwon-si (KR)

(72) Inventors: Gunwoo KIM, Suwon-si (KR); Seongho SON, Suwon-si (KR); Jongsung LEE, Suwon-si (KR); Changjoon LEE, Suwon-si (KR); Seonghwan SHIN, Suwon-si (KR); Tackmo LEE, Suwon-si (KR); Soonmin HONG, Suwon-si (KR)

(73) Assignee: SAMSUNG ELECTRONICS CO., LTD., Suwon-si (KR)

(21) Appl. No.: 18/674,482

(22) Filed: May 24, 2024

Related U.S. Application Data
(63) Continuation of application No. PCT/KR2022/014469, filed on Sep. 27, 2022.

(30) Foreign Application Priority Data
Nov. 24, 2021 (KR) 10-2021-0163482
Jan. 4, 2022 (KR) 10-2022-0001157

(51) Int. Cl. H01L 33/64; H01L 25/16; H01L 27/12

(52) U.S. Cl. CPC H01L 33/644; H01L 25/167; H01L 27/124

(57) ABSTRACT

A display apparatus includes: a display module array including a plurality of display modules arranged in a matrix, wherein each display module of the plurality of display modules includes: a substrate including a mounting surface and a rear surface opposite to the mounting surface; a plurality of inorganic light-emitting elements mounted on the mounting surface of the substrate; a metal plate adhered to the rear surface of the substrate and configured to dissipate heat generated by the substrate; a front cover covering the mounting surface; a first conductive layer on the mounting surface; and a second conductive layer between the front cover and the first conductive layer.

### CROSS-REFERENCE TO RELATED APPLICATIONS

This application is a by-pass continuation application of International Application No. PCT/KR2022/014469, filed on Sep. 27, 2022, which is based on and claims priority to Korean Patent Application Nos. 10-2021-0163482, filed on Nov. 24, 2021, and 10-2022-0001157 filed on Jan. 4, 2022, in the Korean Intellectual Property Office, the disclosures of which are incorporated by reference herein in their entireties.

### BACKGROUND

### 1. Field

The disclosure relates to a display apparatus, and more particularly, to a display apparatus with enhanced electrostatic discharge (ESD) durability.

### 2. Description of Related Art

A display apparatus is a kind of output device for visually displaying images and data information, such as characters or figures, for example.

As a display apparatus, a liquid crystal panel using a backlight or an Organic Light-Emitting Diode (OLED) panel configured with a film of an organic compound that itself emits light in response to current has been widely used. However, the liquid crystal panel has a slow response time and high power consumption, and uses a backlight because itself cannot emit light. Accordingly, it is difficult to make the liquid crystal panel more compact. Also, the OLED panel does not require a backlight and can achieve a small thickness because itself can emit light. However, the OLED panel is vulnerable to a burn-in phenomenon in which, if the same screen is displayed for a long time and then changes to another screen, an area of the previous screen remains as it is due to the short lifespan of the sub pixels. For these reasons, as a new panel that will substitute these, a micro light-emitting diode (referred to as a micro LED or a μLED) panel that uses inorganic light-emitting elements mounted on substrates as pixels is being studied.

The micro light-emitting diode display panel (hereinafter, referred to as a micro LED panel), which is a flat display panel, is configured with a plurality of inorganic LEDs each having a size of 100 micrometers or less.

The micro LED panel does not cause the burn-in phenomenon of OLEDs as inorganic light-emitting elements that are self-emissive devices, while having excellent brightness, resolution, consumption power, and durability.

The micro LED display panel provides better contrast, response time, and energy efficiency than the LCD panel using the backlight. Micro LEDs which are inorganic light-emitting elements have higher brightness, higher light-emitting efficiency, and a longer lifespan than OLEDs although both the OLEDs and micro LEDs have high energy efficiency.

Also, display modules can be manufactured in unit of substrates by arranging LEDs in unit of pixels on circuit boards, and accordingly, micro LED display panels can be manufactured with various resolutions and screen sizes according to consumers' orders.

### SUMMARY

Provided is a display apparatus that may prevent electronic components mounted on a substrate from being damaged by an electrostatic discharge.

Further, provided is a display apparatus with an improved ESD withstanding voltage of electronic components mounted on a substrate.

Further, provided is a display apparatus with reduced visibility of seams.

According to an aspect of the disclosure, a display apparatus includes: a display module array including a plurality of display modules arranged in a matrix, wherein each display module of the plurality of display modules includes: a substrate including a mounting surface and a rear surface opposite to the mounting surface; a plurality of inorganic light-emitting elements mounted on the mounting surface of the substrate; a metal plate adhered to the rear surface of the substrate and configured to dissipate heat generated by the substrate; a front cover covering the mounting surface; a first conductive layer on the mounting surface; and a second conductive layer between the front cover and the first conductive layer.

Each display module of the plurality of display modules may further include an adhesive layer between the first conductive layer and the second conductive layer.

The adhesive layer may include a nonconductor.

Each display module of the plurality of display modules may further include an optical sheet between the front cover and the second conductive layer.

The second conductive layer may be grounded to outside of each display module of the plurality of display modules.

The second conductive layer may be exposed to outside of each display module of the plurality of display modules.

Each display module of the plurality of display modules may further include an insulating layer between the second conductive layer and the adhesive layer.

Each display module of the plurality of display modules may further include a driving circuit board on the metal plate and configured to electrically control the plurality of inorganic light-emitting elements, the substrate may further include: a side surface; a chamfer portion between the mounting surface and the side surface and between the rear surface and the side surface; a side wiring extending along the side surface and the chamfer portion and electrically connecting the plurality of inorganic light-emitting elements to the driving circuit board, and the second conductive layer extends further in a side direction than the side wiring.

The first conductive layer is an anisotropic conductive layer, and the second conductive layer may include a transparent conductive oxide.

The display apparatus may further include a frame configured to support the front cover, and the second conductive layer of each display module of the plurality of display modules is positioned toward the front cover and spaced from the first conductive layer of the display module.

Each display module of the plurality of display modules may further include an optical sheet between the front cover and the second conductive layer.

The second conductive layer of each display module of the plurality of display modules may be grounded to outside of the display module.

The second conductive layer each display module of the plurality of display modules is exposed to outside of the display module.

According to an aspect of the disclosure, a display module includes: a substrate including: a mounting surface; a rear surface opposite to the mounting surface; and a side surface; a plurality of inorganic light-emitting elements mounted on the mounting surface of the substrate; a front cover covering the mounting surface and including a side end extending to an outer area from the mounting surface; a side cover covering the side surface and adhered on a lower surface of the front cover corresponding to the outer area from the mounting surface and the side surface of the substrate; a metal plate adhered on the rear surface and configured to dissipate heat generated by the substrate; an adhesive layer between the substrate and the front cover and configured to adhere the front cover to the substrate; and a conductive layer between the front cover and the adhesive layer.

The display module may further include an anisotropic conductive layer on the mounting surface.

The display module may further include an optical sheet between the front cover and the conductive layer.

The conductive layer may be grounded to outside of the display module or exposed to the outside of the display module.

The conductive layer may include a transparent conductive oxide.

According to an aspect of the disclosure, a display module includes: a substrate including: a mounting surface; a rear surface opposite to the mounting surface; and a side surface; a plurality of inorganic light-emitting elements mounted on the mounting surface of the substrate; a metal plate adhered on the rear surface; a front cover covering the mounting surface; an optical sheet between the substrate and the front cover; an anisotropic conductive layer applied on the mounting surface; a transparent conductive oxide between the optical sheet and the anisotropic conductive layer; and an adhesive layer between the anisotropic conductive layer and the transparent conductive oxide and including a nonconductor.

The transparent conductive oxide may be grounded to outside of the display module or exposed to the outside of the display module.

### BRIEF DESCRIPTION OF THE DRAWINGS

The above and other aspects, features, and advantages of certain embodiments of the present disclosure are more apparent from the following description taken in conjunction with the accompanying drawings, in which:

FIG. 1 shows a display apparatus according to one or more embodiments.

FIG. 2 is an exploded view showing main components of the display apparatus of FIG. 1.

FIG. 3 is an enlarged cross-sectional view showing some components of a display module shown in FIG. 1.

FIG. 4 is a rear perspective view of a display module of the display apparatus shown in FIG. 1.

FIG. 5 is a perspective view showing some components of a display module shown in FIG. 1.

FIG. 6 is a cross-sectional view showing some components of the display apparatus of FIG. 1, taken in a second direction.

FIG. 7 is an enlarged cross-sectional view of some components shown in FIG. 6.

FIG. 8 is a cross-sectional view showing some components of the display apparatus of FIG. 1, taken in a third direction.

FIG. 9 is an enlarged cross-sectional view of some components shown in FIG. 8.

FIG. 10 is an enlarged cross-sectional view showing some components of a display module in a display apparatus according to one or more embodiments.

FIG. 11 schematically shows an electrostatic discharge (ESD) flow at a display module in a display apparatus according to one or more embodiments.

FIG. 12 schematically shows an ESD flow at a display module in a display apparatus according to one or more embodiments.

FIG. 13 schematically shows an ESD flow at a display module in a display apparatus according to one or more embodiments.

FIG. 14 schematically shows an ESD flow at a display module in a display apparatus according to one or more embodiments.

### DETAILED DESCRIPTION

Configurations illustrated in the drawings and the embodiments described in the present specification are only example embodiments of the present disclosure, and thus it is to be understood that various modified examples, which may replace the embodiments and drawings of the present specification, are possible when filing the present application.

Also, like reference numerals or symbols denoted in the drawings of the present specification represent members or components that perform the substantially same functions.

Also, the terms used in the present specification are merely used to describe one or more embodiments, and are not intended to limit and/or restrict the disclosure. An expression used in the singular encompasses the expression of the plural, unless it has a clearly different meaning in the context. In the present specification, it is to be understood that the terms such as “comprising”, “including” or “having”, for example, are intended to indicate the existence of the features, numbers, steps, operations, components, parts, or combinations thereof disclosed in the specification, and are not intended to preclude the possibility that one or more other features, numbers, steps, operations, components, parts, or combinations thereof may exist or may be added.

Also, it will be understood that, although the terms including ordinal numbers, such as “first”, or “second”, for example, may be used herein to describe various components, these components should not be limited by these terms. The above terms are used only to distinguish one component from another. For example, a first component could be termed a second component, and similarly, a second component may be termed a first component without departing from the scope of right of the disclosure. The term “and/or” includes any and all combinations of one or more of a plurality of associated listed items.

Also, in this specification, the meaning of ‘identical’ may include similar in attribute or similar within a range. Also, the term ‘identical’ means ‘substantially identical’. The meaning of ‘substantially identical’ needs to be understood that a value falling within the margin of error in manufacturing or a value corresponding to a difference within a meaningless range with respect to a reference value is included in the range of ‘identical’.

In the following description, the terms “front”, “rear”, “left”, and “right” are defined based on the drawings, and the shapes and positions of the components are not limited by the terms.

Hereinafter, embodiments of the disclosure will be described in detail with reference to the accompanying drawings.

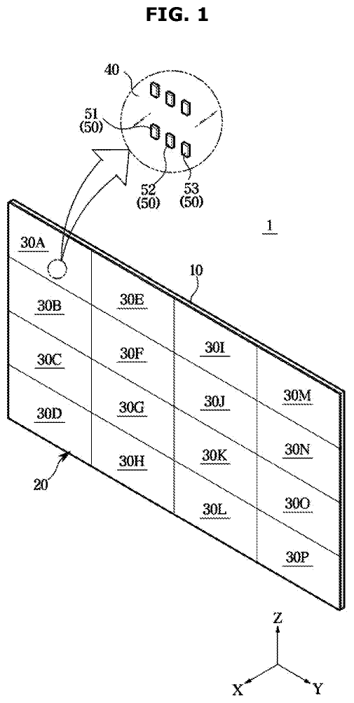

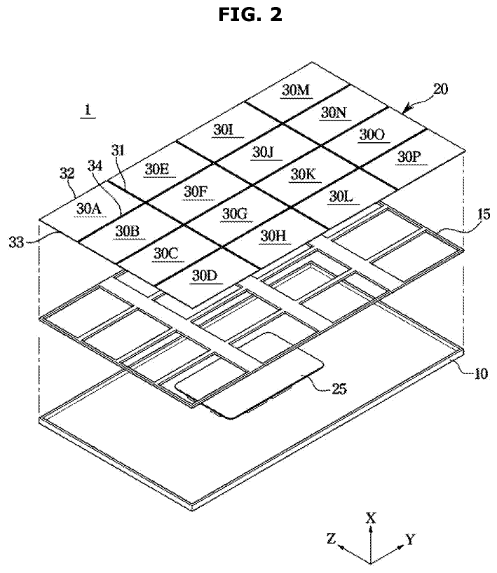

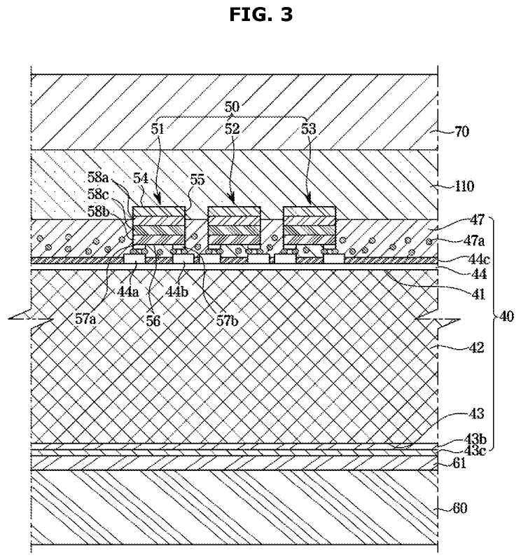

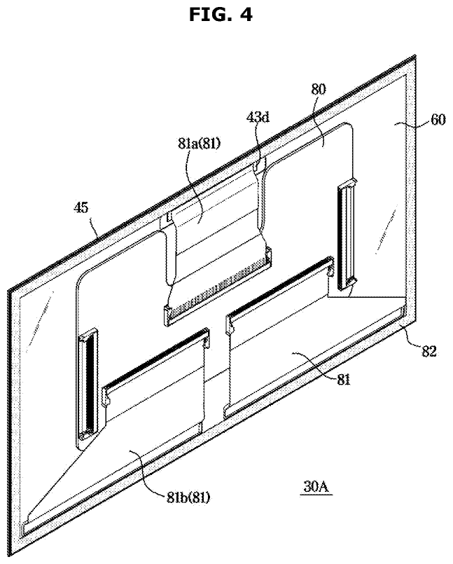

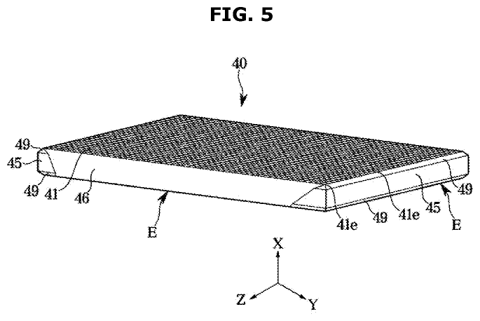

FIG. 1 shows a display apparatus according to one or more embodiments, FIG. 2 is an exploded view showing main components of the display apparatus of FIG. 1, FIG. 3 is an enlarged cross-sectional view showing some components of a display module shown in FIG. 1, FIG. 4 is a rear perspective view of a display module of the display apparatus shown in FIG. 1, and FIG. 5 is a perspective view showing some components of a display module shown in FIG. 1.

Some components of a display apparatus 1, including a plurality of inorganic light-emitting elements 50, shown in the drawings may be micro-scale components each having a size of several micrometers (μm) to hundreds of micrometers (μm), and for convenience of descriptions, some components (the plurality of inorganic light emitting devices 50, for example) are exaggerated in scale.

The display apparatus 1 may be a device for displaying information and data as characters, figures, graphs, images, for example, and the display apparatus 1 may be a television (TV), a personal computer (PC), a mobile device, or a digital signage, for example.

According to one or more embodiments, as shown in FIGS. 1 and 2, the display apparatus 1 may include a display panel 20 for displaying an image, a power supply device for supplying power to the display panel 20, a main board 25 for controlling overall operations of the display panel 20, a frame 15 supporting the display panel 20, and a rear cover 10 covering a rear surface of the frame 15.

The display panel 20 may include a plurality of display modules 30A to 30P, a driving board for driving the individual display modules 30A to 30P, and a timing controller (TOCN) board for generating timing signals for respectively controlling the display modules 30A to 30P.

The rear cover 10 may support the display panel 20. The rear cover 10 may be installed on a floor through a stand, or mounted on a wall through a hanger, for example.

The plurality of display modules 30A to 30P may be arranged in up, down, left, and right directions to be adjacent to each other. The plurality of display modules 30A to 30P may be arranged in a form of a M*N matrix. In the current embodiment, 16 display modules 30A to 30P may be arranged in a form of a 4*4 matrix. However, a number and arrangement of the plurality of display modules 30A to 30P are not limited.

The plurality of display modules 30A to 30P may be mounted on the frame 15. The plurality of display modules 30A to 30P may be mounted on the frame 15 by various known methods, such as a magnetic force generated by a magnet or a mechanical insert structure. A rear side of the frame 15 may be coupled with the rear cover 10, and the rear cover 10 may form a rear outer appearance of the display apparatus 1.

The rear cover 10 may include a metal material. Accordingly, heat generated from the plurality of display modules 30A to 30P and the frame 15 may be easily transferred to the rear cover 10, which raises heat dissipation efficiency of the display apparatus 1.

As such, the display apparatus 1 according to one or more embodiments may implement a large screen by tiling the plurality of display modules 30A to 30P.

Each of the plurality of display modules 30A to 30P may be applied to a display apparatus. That is, the display modules 30A to 30P may be, in unit of a piece, installed in and applied to a wearable device, a portable device, a handheld device, various electronic products, or electronic parts using a display, Also, the display modules 30A to 30P may be applied to a display apparatus, such as a monitor for PC, a high-resolution TV, a signage, or an electronic display, for example, by being assembled and arranged in a matrix type.

The plurality of display modules 30A to 30P may have the same configuration. Accordingly, the following description about a display module may be applied in the same way to all the other display modules.

Hereinafter, a first display module 30A of the plurality of display modules 30A to 30P will be described because the plurality of display modules 30A to 30P have the same configuration.

That is, to avoid duplicate descriptions, as components of the plurality of display modules 30A to 30P, a display module 30, a substrate 40, and a front cover 70 will be representatively described.

Also, the first display module 30A of the plurality of display modules 30A to 30P and a second display module 30E being adjacent to the first display module 30A in a second direction Y or a third display module 30B being adjacent to the first display module 30A in a third direction Z will be described.

The first display module 30A of the plurality of display modules 30A to 30P may be formed, for example, in a quadrangle type. The first display module 30A may be formed in a rectangle type or a square type.

Accordingly, the first display module 30A may include edges 31, 32, 33, and 34 located in upper, lower, left, and right directions with respect to a first direction X which is a front direction.

As shown in FIG. 3, each of the plurality of display modules 30A to 30P may include the substrate 40, and the plurality of inorganic light-emitting elements 50 mounted on the substrate 40. The plurality of inorganic light-emitting elements 50 may be mounted on a mounting surface 41 of the substrate 40 toward the first direction X. The mounting surface 41 may be a first surface 41. In FIG. 3, for convenience of descriptions, a thickness in first direction X of the substrate 400 is shown to be exaggeratedly great.

The substrate 40 may be formed in a quadrangle type. As described above, because each of the plurality of display modules 30A to 30P is formed in a quadrangle type, the substrate 40 may also be formed in a quadrangle type correspondingly.

The substrate 40 may be formed in a rectangle type or a square type.

Accordingly, in the example of the first display module 30A, the substrate 40 may include four edges E corresponding to the edges 31, 32, 33, and 34 of the first display module 30A, formed in the upper, lower, left, and right directions with respect to the first direction X which is the front direction (see FIG. 5).

The substrate 40 may include a substrate body 42, the mounting surface 41 forming one surface of the substrate body 42, a rear surface 43 forming another surface of the substrate body 42 and being opposite to the mounting surface 41, and a side surface 45 positioned between the mounting surface 41 and the rear surface 43.

The side surface 45 may form side ends of the substrate 40 in the second direction Y and the third direction Z that are orthogonal to the first direction X.

The substrate 40 may include a chamfer portion 49 formed between the mounting surface 41 and the side surface 45 and between the rear surface 43 and the side surface 45.

The chamfer portion 49 may prevent, upon an arrangement of the plurality of display modules 30A to 30P, each substrate from colliding with another one(s) and being damaged.

The edges E of the substrate 40 may include the side surface 45 and the chamfer portion 49.

The substrate 40 may include a Thin Film Transistor (TFT) layer 44 formed on the substrate body 42 to drive the inorganic light-emitting elements 50. The substrate body 42 may include a glass substrate. That is, the substrate 40 may include a Chip on Glass (COG) type substrate. On the substrate 40, first and second pad electrodes 44a and 44b may be formed to electrically connect the inorganic light-emitting elements 50 to the TFT layer 44.

TFTs configuring the TFT layer 44 are not limited to specific structures or types, and may be implemented as various embodiments. That is, TFTs of the TFT layer 44 according to one or more embodiments may be implemented as Low Temperature Poly Silicon (LTPS) TFTs, oxide TFTs, Si (poly silicon or a-silicon) TFTs, organic TFTs, or graphene TFTs.

Also, the TFT layer 44 may be replaced with a Complementary Metal-Oxide Semiconductor (CMOS) type, n-type MOSFT, or p-type MOSFET transistor, in a case in which the substrate body 42 of the substrate 40 is a silicon wafer.

The plurality of inorganic light-emitting elements 50 may be formed of an inorganic material, and each of the inorganic light-emitting elements 50 may have sizes of several micrometers (μm) to hundreds of micrometers (μm) in width, length, and height. A micro inorganic light-emitting element may have a shorter side length of 100 μm or less in width, length, and height. That is, the inorganic light-emitting elements 50 may be picked up from a sapphire or silicon wafer and then directly transferred onto the substrate 40. The plurality of inorganic light-emitting elements 50 may be picked up and conveyed through an electrostatic method using an electrostatic head or a stamp method using an elastic polymer material, such as PDMS or silicon, as a head.

The plurality of inorganic light-emitting elements 50 may be a light-emitting structure including an n-type semiconductor 58a, an active layer 58c, a p-type semiconductor 58b, a first contact electrode 57a, and a second contact electrode 57b.

Any one of the first contact electrode 57a and the second contact electrode 57b may be electrically connected to the n-type semiconductor 58a, and another one may be electrically connected to the p-type semiconductor 58b.

The first contact electrode 57a and the second contact electrode 57b may be a flip chip type arranged horizontally toward the same direction (an opposite direction of a light-emitting direction).

Each inorganic light-emitting element 50 may include a light-emitting surface 54 positioned toward the first direction X upon being mounted on the mounting surface 41, a side surface 55, and a bottom surface 56 being opposite to the light-emitting surface 54, and the first contact electrode 57a and the second contact electrode 57b may be formed on the bottom surface 56.

That is, the contact electrodes 57a and 57b of the inorganic light-emitting element 50 may be opposite to the light-emitting surface 54, and accordingly, the contact electrodes 57a and 57b may be positioned in the opposite direction of the light-emitting direction.

The contact electrodes 57a and 57b may face the mounting surface 41, and be electrically connected to the TFT layer 44. The light-emitting surface 54 through which light is irradiated may be positioned in an opposite direction of the direction in which the contact electrodes 57a and 57b are positioned.

Accordingly, light generated by the active layer 58c may be irradiated toward the first direction X through the light-emitting surface 54, without any interference by the first contact electrode 57a or the second contact electrode 57b.

That is, the first direction X may be defined as a direction in which the light-emitting surface 54 is positioned to irradiate light.

The first contact electrode 57a and the second contact electrode 57b may be electrically connected respectively to the first pad electrode 44a and the second pad electrode 44b formed on the mounting surface 41 of the substrate 40.

The inorganic light-emitting element 50 may be connected directly to the pad electrodes 44a and 44b through an anisotropic conductive layer 47 or a bonding material such as a solder.

On the substrate 40, the anisotropic conductive layer 47 may be formed to mediate an electrical connection between the contact electrodes 57a and 57b and the pad electrodes 44a and 44b. The anisotropic conductive layer 47 may be formed by applying an anisotropic conductive adhesive on a protective film, and have a structure in which conductive balls 47a are distributed in an adhesive resin. Each conductive ball 47a may be a conductive sphere surrounded by a thin insulating film, and as a result of breaking of the insulating film by pressure, the conductive ball 47a may electrically connect a conductor to another one.

The anisotropic conductive layer 47 may include an Anisotropic Conductive Film (ACF) being in a form of a film, and an Anisotropic Conductive Paste (ACP) being in a form of a paste.

In one or more embodiments, the anisotropic conductive layer 47 may be provided as an anisotropic conductive film.

Accordingly, the insulating films of the conductive balls 47a may be broken by pressure applied to the anisotropic conductive layer 47 upon mounting of the plurality of inorganic light-emitting elements 50 on the substrate 40, and as a result, the contact electrodes 57a and 57b of the inorganic light-emitting elements 50 may be electrically connected to the pad electrodes 44a and 44b of the substrate 40.

The plurality of inorganic light-emitting elements 50 may be mounted on the substrate 40 through a solder, instead of the anisotropic conductive layer 47. By performing a reflow process after arranging the inorganic light-emitting elements 50 on the substrate 40, the inorganic light-emitting elements 50 may be adhered on the substrate 40.

The anisotropic conductive layer 47 may be formed with a dark color. For example, the anisotropic conductive layer 47 may improve contrast of a screen by absorbing external light such that the substrate 40 is shown to be black. The anisotropic conductive layer 47 formed with the dark color may function to supplement the light absorbing layer 44c formed on the entire of the mounting surface 41 of the substrate 40.

The plurality of inorganic light-emitting elements 50 may include a red light-emitting device 51, a green light-emitting device 52, and a blue light-emitting device 53. The inorganic light-emitting elements 50 may be mounted in unit of a group including the red light-emitting device 51, the green light-emitting device 52, and the blue light-emitting device 53 on the mounting surface 41 of the substrate 40. The red light-emitting device 51, the green light-emitting device 52, and the blue light-emitting device 53 may form a pixel. In this case, each of the red light-emitting device 51, the green light-emitting device 52, and the blue light-emitting device 53 may form a sub pixel.

The red light-emitting device 51, the green light-emitting device 52, and the blue light-emitting device 53 may be aligned with preset intervals, as in one or more embodiments, or may be arranged in another form such as a triangle.

The substrate 40 may include a light absorbing layer 44c for absorbing external

light to improve contrast. The light absorbing layer 44c may be formed on the entire of the mounting surface 41 of the substrate 40. The light absorbing layer 44c may be formed between the TFT layer 44 and the anisotropic conductive layer 47.

Each of the plurality of display modules 30A to 30P may include a front cover 70 positioned in the front direction X on the mounting surface 41 of the display module 30A to 30P to cover the mounting surface 41.

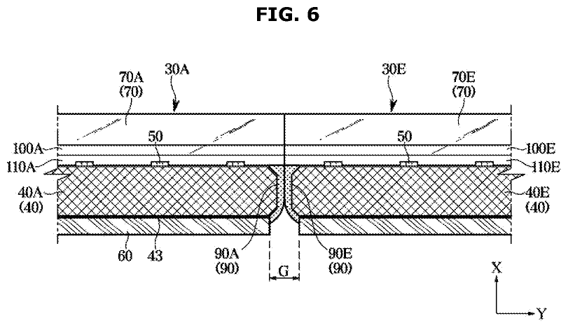

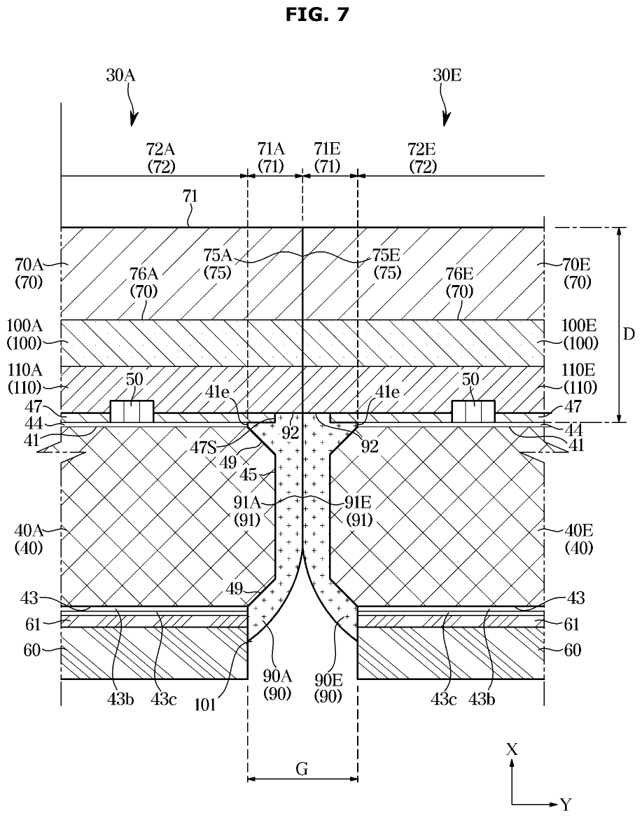

A plurality of front covers 70 may be respectively formed in the first direction X on the plurality of display modules 30A to 30P (see FIGS. 6 and 7).

The plurality of display modules 30A to 30P may be assembled with each other after the front covers 70 are respectively formed on the display modules 30A to 30P. That is, in an example of the first display module 30A and the second display module 30E among the plurality of display modules 30A to 30P, a first front cover 70A may be formed on the mounting surface 41 of the first display module 30A and a second front cover 70E may be formed on the mounting surface 41 of the second display module 30E.

The front cover 70 may cover the substrate 40 to protect the substrate 40 against an external force or outside water.

A plurality of layers of the front cover 70 may be provided as a functional film having optical performance. This will be described in detail, later.

Some of the plurality of layers of the front cover 70 may include a base layer formed of an optical clear resin (OCR). The base layer may support the plurality of other layers. The OCR may be in a very transparent state because the OCR has transmittance of 90% or more.

The OCR may improve visibility and image quality by raising transmittance through a low reflection property. That is, in a structure having an air gap, light loss occurs due to a refractive index difference between a film layer and an air layer. However, in a structure having an OCR, such a refractive index difference may be reduced to decrease light loss, resulting in an improvement of visibility and image quality.

That is, the OCR may improve image quality while protecting the substrate 40.

The display apparatus may include an adhesive layer 110 (also 110A and 110E) for adhering the front cover 70 to the mounting surface 41 of the substrate 40.

The front cover 70 may have a height that is greater than or equal to a preset height in the first direction X which the mounting surface 41 or the light-emitting surface 54 faces.

The reason may be to sufficiently fill a gap that may be formed between the front cover 70 and the plurality of inorganic light-emitting elements 50 when the front cover 70 is formed on the substrate 40.

Also, each of the plurality of display modules 30A to 30P may include a rear adhesive layer 61 positioned between the rear surface 43 and the metal plate 60 to adhere the metal plate 60 to the rear surface 43 of the substrate 40.

The rear adhesive layer 61 may be a double-sided tape, although not limited thereto. However, the rear adhesive layer 101 may be an adhesive layer, not a tape. That is, the rear adhesive layer 61 may be an embodiment of a medium for adhering the metal plate 60 to the rear surface 43 of the substrate 40, and the rear adhesive layer 61 may be provided as one of various mediums, without being limited to a tape.

The plurality of inorganic light-emitting elements 50 may be electrically connected to a pixel driving wiring formed on the mounting surface 41, and an upper wiring layer extending through the side surface 45 of the substrate 40 and formed with a pixel driving wiring.

The upper wiring layer may be formed below the anisotropic conductive layer 47. The upper wiring layer may be electrically connected to a side wiring 46 formed on the side surface 45 of the substrate 40. The side wiring 46 may be provided in a form of a thin film.

Under an assumption that the second direction Y is a left-right direction of the display apparatus 1, being orthogonal to the first direction X toward the front direction of the display apparatus 1, and the third direction Z is an up-down direction of the display apparatus 1, being orthogonal to the first direction X and the second direction Y, the side wiring 46 may extend to the rear surface 43 of the substrate 40 in the third direction Z along the chamfer portion 49 and the side surface 45 of the substrate 40 extending in the third direction Z, although not limited thereto.

However, the wiring 46 may extend to the rear surface 43 of the substrate 40 in the second direction Y along the chamfer portion 49 and the side surface 45 of the substrate 40 extending in the second direction Y.

According to one or more embodiments, the side wiring 46 may extend along the edges E of the substrate 40, corresponding to the upper edge 32 and the lower edge 34 of the first display module 30A, although not limited thereto.

However, the side wiring 46 may extend along the edges E of the substrate 40, corresponding to at least two edges of the four edges 31, 32, 33, and 34 of the first display module 30A.

The upper wiring layer may be connected to the side wiring 46 by an upper connecting pad formed on the edges E of the substrate 40.

The side wiring 46 may extend along the side surface 45 of the substrate 40 and be connected to a rear wiring layer 43b formed on the rear surface 43.

An insulating layer 43c may be formed on the rear wiring layer 43b in a direction which the rear surface 43 of the substrate 40 faces, to cover the rear wiring layer 43b.

That is, the plurality of inorganic light-emitting elements 50 may be electrically connected to the upper wiring layer, the side wiring 46, and the rear wiring layer 43b, sequentially.

Also, as shown in FIG. 4, the display module 30A may include a driving circuit board 80 for electrically controlling the plurality of inorganic light-emitting elements 50 mounted on the mounting surface 41. The driving circuit board 80 may be a printed circuit board. The driving circuit board 80 may be positioned on the rear surface 43 of the substrate 40 in the first direction X. The driving circuit board 80 may be positioned on the metal plate 60 adhered on the rear surface 43 of the substrate 40.

The display module 30A may include a flexible film 81 connecting the driving circuit board 80 to the rear wiring layer 43b to electrically connect the driving circuit board 80 to the plurality of inorganic light-emitting elements 50.

More specifically, one end of the flexible film 81 may be connected to a rear connecting pad 43d positioned on the rear surface 43 of the substrate 40 and electrically connected to the plurality of inorganic light-emitting elements 50.

The rear connecting pad 43d may be electrically connected to the rear wiring layer 43b. Accordingly, the rear connecting pad 43d may electrically connect the rear wiring layer 43b to the flexible film 81.

Because the flexible film 81 is electrically connected to the rear connecting pad 43d, the flexible film 81 may transfer power and an electrical signal from the driving circuit board 80 to the plurality of inorganic light-emitting elements 50.

The flexible film 81 may be a Flexible Flat Cable (FFC) or a Chip On Film (COF).

The flexible film 81 may include a first flexible film 81a and a second flexible film 81b respectively positioned in upper and lower directions with respect to the first direction X which is the front direction, although not limited thereto.

However, the first and second flexible films 81a and 81b may be positioned in left and right directions with respect to the first direction X, or in at least two directions of the upper, lower, left, and right directions.

A plurality of second flexible films 81b may be provided, although not limited thereto. However, a single second flexible film 81b may be provided, and a plurality of first flexible films 81a may also be provided.

The first flexible film 81a may transfer a data signal from the driving circuit board 80 to the substrate 40. The first flexible film 81a may be a COF, although not limited thereto.

The second flexible film 81b may transfer power from the driving circuit board 80 to the substrate 40. The second flexible film 81b may be a FFC, although not limited thereto.

However, the first and second flexible films 81a and 81b may be a COF and a FFC, respectively.

The driving circuit board 80 may be electrically connected to the main board 25 (see FIG. 2). The main board 25 may be positioned behind the frame 15, and the main board 25 may be connected to the driving circuit board 80 through a cable behind the frame 15.

As described above, the metal plate 60 may be in contact with the substrate 40. The metal plate 60 may be adhered to the substrate 40 by the rear adhesive layer 61 positioned between the rear surface 43 of the substrate 40 and the metal plate 60.

The metal plate 60 may be formed of a metal material having high heat conductivity. For example, the metal plate 60 may be formed of an aluminum material.

Heat generated from the TFT layer 44 and the plurality of inorganic light-emitting elements 50 mounted on the substrate 40 may be transferred to the metal plate 60 through the rear adhesive layer 101 along the rear surface 43 of the substrate 40.

Accordingly, heat generated from the substrate 40 may be easily transferred to the metal plate 60 to prevent temperature of the substrate 40 from rising to preset temperature or more.

The plurality of display modules 30A to 30P may be arranged at various locations in a form of a M×N matrix. The individual display modules 30A to 30P may be movable independently. In this case, each of the display modules 30A to 30P may include the metal plate 60 to maintain a level of heat dissipation performance regardless of the locations of the display modules 30A to 30P.

The plurality of display modules 30A to 30P may be arranged in forms of various M×N matrices to implement various screen sizes of the display apparatus 1. Accordingly, radiating heat from the individual display modules 30A to 30P by including the metal plate 60 in each of the display modules 30A to 30P as in one or more embodiments may more improve total heat-radiating performance of the display apparatus 1 than radiating heat through a single metal plate provided for temporary heat radiation.

In a case in which a single metal plate is positioned inside the display apparatus 1, the metal plate may not exist at a location corresponding to a location of some display modules in a front-rear direction while existing at a location where no display module is positioned, resulting in deterioration of heat dissipation efficiency of the display apparatus 1.

That is, all of the individual display modules 30A to 30P may radiate heat through the metal plate 60 positioned in each of the display modules 30A to 30P regardless of the locations, which leads to an improvement of total heat dissipation performance of the display apparatus 1.

The metal plate 60 may be in a shape of a rectangle substantially corresponding to a shape of the substrate 40.

An area of the substrate 40 may be at least equal to or larger than an area of the metal plate 60. According to a parallel arrangement in first direction X of the substrate 40 and the metal plate 60, the four edges E of the substrate 40 being in a shape of a rectangle may correspond to four edges of the metal plate 60 with respect to centers of the substrate 40 and the metal plate 60, or the four edges E of the substrate 40 may be positioned at outer locations than the four edges of the metal plate 60 with respect to the centers of the substrate 40 and the metal plate 60.

For example, the four edges E of the substrate 40 may be positioned at the outer locations than the four edges of the metal plate 60. That is, the area of the substrate 40 may be larger than the area of the metal plate 60.

Upon transferring of heat to the individual display modules 30A to 30P, the substrate 40 and the metal plate 60 may be heat-expanded, wherein a degree of expansion of the metal plate 60 may be greater than a degree of expansion of the substrate 40 because the metal plate 60 has a greater coefficient of thermal expansion than the substrate 40.

In a case in which the four edges E of the substrate 40 correspond to the four edges or the metal plate 60 or are positioned at inner locations than the four edges of the metal plate 60, the edges of the metal plate 60 may protrude to an outer location than the substrate 40.

As a result, lengths of gaps formed between the display modules 30A to 30P may become non-uniform by thermal expansion of the metal plate 60 of each of the display modules 30A to 30P, and accordingly, recognition of some seams may rise, which deteriorates a sense of unity of a screen of the display panel 20.

However, in a case in which the four edges E of the substrate 40 are positioned at the outer locations than the four edges of the metal plate 60, the metal plate 60 may not protrude to the outer location than the four edges E of the substrate 40 although the substrate 40 and the metal plate 60 are heat-expanded, and accordingly, the lengths of the gaps formed between the display modules 30A to 30P may be maintained uniform.

In addition, to maintain constant separation distances of gaps formed between the display modules 30A to 30P, the frame 15 supporting the display modules 30A to 30P may include a front surface having a similar material property to that of the substrate 40. That is, the display modules 30A to 30P may be adhered on the front surface of the frame 15.

According to one or more embodiments, the area of the substrate 40 may substantially correspond to the area of the metal plate 60. Accordingly, heat generated from the substrate 40 may be uniformly dissipated over the entire area of the substrate 40 without being isolated in some areas.

The metal plate 60 may be adhered on the rear surface 43 of the substrate 40 by the rear adhesive layer 61.

The rear adhesive layer 61 may have a size corresponding to the metal plate 60. That is, an area of the rear adhesive layer 61 may correspond to the area of the metal plate 60. The metal plate 60 may be substantially in a shape of a rectangle, and the rear adhesive layer 61 may also be in a shape of a rectangle correspondingly.

The edges of the metal plate 60 being in the shape of the rectangle may correspond to the edges of the rear adhesive layer 61 being in the shape of the rectangle with respect to centers of the metal plate 60 and the rear adhesive layer 61.

Accordingly, the metal plate 60 and the rear adhesive layer 61 may be easily manufactured as a coupled configuration, thereby increasing manufacturing efficiency of the display apparatus 1.

That is, before a plate is cut into unit pieces to form the metal plate 60, the rear adhesive layer 61 may be adhered on the plate and then the rear adhesive layer 61 and the metal plate 60 may be cut together into unit pieces to form the metal plate 60, thereby reducing a number of processes.

Heat generated from the substrate 40 may be transferred to the metal plate 60 through the rear adhesive layer 61. Accordingly, the rear adhesive layer 61 may adhere the metal plate 60 on the substrate 40, while transferring heat generated from the substrate 40 to the metal plate 60.

Accordingly, the rear adhesive layer 61 may include a material having high heat dissipation performance.

The rear adhesive layer 61 may include, basically, a material having an adhesive property to adhere the substrate 40 to the metal plate 60.

Additionally, the rear adhesive layer 61 may include a material having high heat dissipation performance rather than materials having an adhesive property. Accordingly, the rear adhesive layer 61 may efficiently transfer heat between the substrate 40 and the metal plate 60.

Also, the material having the adhesive property of the rear adhesive layer 61 may be a material having higher heat dissipation performance than adhesive materials constituting existing adhesives.

The material having the higher heat dissipation performance may be a material capable of effectively transferring heat because the material has high heat conductivity, high heat transfer performance, and low specific heat.

For example, the rear adhesive layer 61 may include a graphite material, although not limited thereto. However, the rear adhesive layer 61 may be formed of any material having high heat dissipation performance.

Flexibility of the rear adhesive layer 61 may be greater than flexibility of the substrate 40 and the metal plate 60. Accordingly, the rear adhesive layer 61 may be formed of a material having an adhesive property, heat dissipation, and high flexibility. The rear adhesive layer 61 may be formed of a baseless double-sided tape. Because the rear adhesive layer 61 is formed of a baseless double-sided tape, as described above, the rear adhesive layer 61 may be formed as a single layer of which one side is adhered on the substrate 40 and the other side is adhered on the metal plate 60, without having any base supporting the one side and the other side.

Because the rear adhesive layer 61 includes no base, the rear adhesive layer 61 may include no material interfering with heat conduction, and accordingly, heat dissipation performance may increase. However, the rear adhesive layer 61 is not limited to a baseless double-sided tape, and may be a heat dissipation tape having higher heat dissipation performance than existing double-sided tapes.

The rear adhesive layer 61 may be formed of a material having high flexibility to absorb an external force transferred from the substrate 40 and the metal plate 60. Flexibility of the rear adhesive layer 61 may be higher than flexibility of the substrate 40 and the metal plate 60.

Accordingly, upon transferring of an external force generated by changed sizes of the substrate 40 and the metal plate 60 by heat transferred to the substrate 40 and the metal plate 60 to the rear adhesive layer 61, the rear adhesive layer 61 may be deformed to prevent the external force from being transferred to the other components.

The rear adhesive layer 61 may have a thickness in the first direction X. The metal plate 60 may be heat-expanded by transferred heat or cooled to be contracted. In this case, the metal plate 60 may be expanded or contracted in the first direction X and directions that are orthogonal to the first direction X, and accordingly, an external force may be transferred to the substrate 40.

As described above, because the metal plate 60 is formed with a size corresponding to the substrate 40 and covers the entire of the rear surface 43 of the substrate 40, a fixing member 82 may be positioned on a rear surface of the metal plate 60, although not limited thereto.

However, the fixing member 82 may be positioned on the rear surface 43 of the substrate 40. In this case, the substrate 40 may be bonded directly on the frame 15 through the fixing member 82.

The metal plate 60 may cover only a portion of the rear surface 43 of the substrate 40, and the fixing member 82 may be adhered on an area not covered by the metal plate 60 in the rear surface 43 of the substrate 40.

The fixing member 82 may be, for example, a double-sided tape.

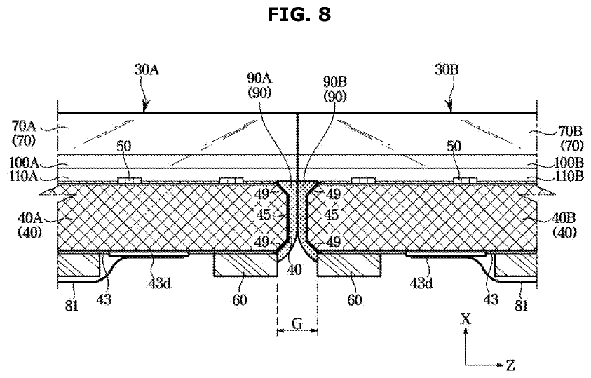

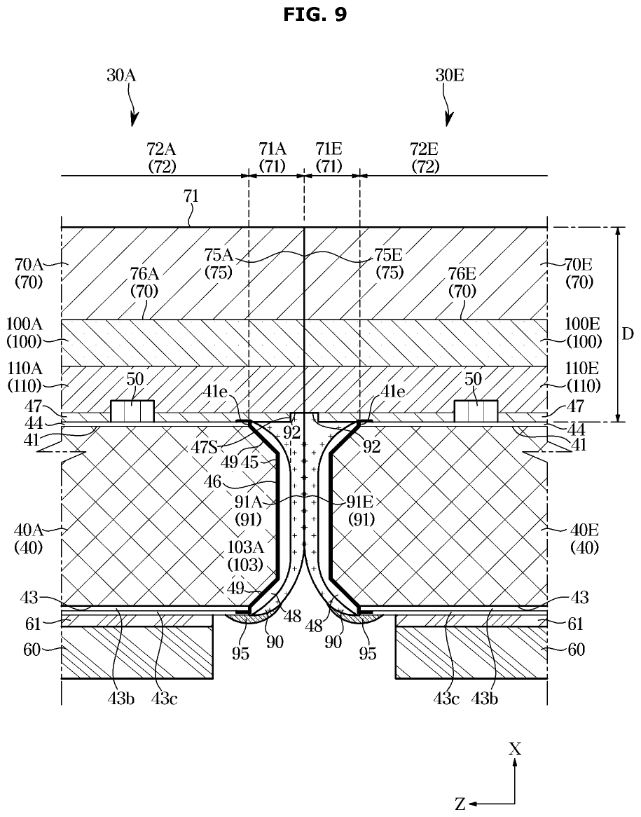

FIG. 6 is a cross-sectional view showing some components of the display apparatus of FIG. 1, taken in the second direction, FIG. 7 is an enlarged cross-sectional view of some components shown in FIG. 6, FIG. 8 is a cross-sectional view showing some components of the display apparatus of FIG. 1, taken in a third direction, and FIG. 9 is an enlarged cross-sectional view of some components shown in FIG. 8.

Referring to FIGS. 6 to 9, the front cover 70 may protect the substrate 40 against external forces and reduce visibility of seams formed by the gaps between the plurality of display modules 30A to 30P while improving color deviation between the plurality of display modules 30A to 30P.

Each of the plurality of display modules 30A to 30P may include the side cover 90 positioned between a gap formed between the plurality of display modules 30A to 30P while the plurality of display modules 30A to 30P are arrayed.

To absorb light reflected in the gaps G between the plurality of display modules 30A to 30P, the front covers 70 of the respective display module 30A to 30P may extend to outer locations than the substrates 40 of the plurality of display module 30A to 30P. Side ends 75 of each front cover 70 may extend to an outer location than the mounting surface 41.

The front cover 70 may extend to an outer location than an edge (or a side end) 41e of the mounting surface 41 of the substrate 40 in the second direction Y and the third direction Z (see FIG. 5).

Substantially, the gaps between the display modules 30A to 30P may be made between side surfaces 45 of the substrates 40 of the display modules 30A to 30P. However, a gap G in one or more embodiments is a non-display area that may be made between the display modules 30A to 30P, and accordingly, the gap G formed between the plurality of display modules 30A to 30P may be understood as a space formed between an edge 41e of a mounting surface 41 of a substrate 40 of one of the display modules 30A to 30P and an edge 41e of a mounting surface 41 of a substrate 40 of a neighboring display module 30A to 30P.

Accordingly, the gap G formed between the plurality of display modules 30A to 30P is a space formed between an edge 41e of a mounting surface 41 of one of the display modules 30A to 30P and an edge 41e of a mounting surface 41 of a neighboring display module 30A to 30P in the second direction Y or the third direction Z.

The front covers 70 extending from the respective display modules 30A to 30P may be positioned at the gaps G between the plurality of display modules 30A to 30P to absorb light irradiated into the gaps G or light reflected from the gaps G, thereby minimizing recognition of seams.

As shown in FIGS. 6 and 7, the front cover 70 may extend to an outer location than the substrate 40 in the second direction Y. The front cover 70 may extend to an outer location than the side surface 45 and the chamfer portion 49 in the second direction Y.

According to one or more embodiments, while an edge of the substrate 40, corresponding to a right edge 31 of the first display module 30A is described, the front cover 70 may extend to an outer location than the four edges E of the substrate 40 in the second direction Y or the third direction Z.

That is, the side ends 75 of the front cover 70, which correspond to edges of the front cover 70, may extend to an outer area of the substrate 40, that is, to an outer area of the mounting surface 41, than the four edges E of the substrate 40 in the second direction Y or the third direction Z.

The front cover 70 may include a plurality of layers having different optical properties. The plurality of layers may be provided in a structure in which the layers are stacked in the first direction X.

The plurality of layers may constitute the front cover 70 by being adhered with each other in the first direction X.

One of the plurality of layers may be an anti-glare layer, although not limited thereto. However, one of the plurality of layers may be an anti-reflective layer or a mixed layer of an anti-glare layer and an anti-reflective layer.

Another one of the plurality of layers may be a light transmittance adjustable layer, although not limited thereto. However, the layer may be a layer having another physical property or including another material, or a layer having another function. For example, the layer may be a circularly polarized layer.

However, a single layer, instead of the plurality of layers, may be provided. The single layer may be a layer capable of implementing all functions of the plurality of layers.

As described above, the display apparatus 1 may include an adhesive layer 110. The adhesive layer 110 may be positioned between the front cover 70 and the mounting surface 41 to adhere the front cover 70 on the mounting surface 41. Accordingly, because the front cover 70 is in close contact with the mounting surface 41 and protects components mounted on the mounting surface 41, the display module 30 may adhere the front cover 70 directly to the substrate 40 without any additional molding component formed between the front cover 70 and the substrate 40.

The adhesive layer 110 may be a component included in the front cover 70. In this case, the adhesive layer 110 may be one of the plurality of layers. For example, the adhesive layer 110 may be positioned at a hindmost location of the plurality of layers in the first direction X and adhered on the mounting surface 41. The adhesive layer 110 may have a height that is greater than or equal to a preset height in the first direction X which the mounting surface 41 or the light-emitting surface 54 faces.

The adhesive layer 110 may include a material having very low electric conductivity. For example, the adhesive layer 110 may include a nonconductor. Also, the adhesive layer 110 may be formed of a nonconductive material through which no charges are transmitted. However, a component or material of the adhesive layer 110 is not limited to the above-mentioned examples.

The front cover 70 may diffuse and reflect light received from the outside to prevent the light from being specularly reflected to dazzle a user's eyes.

By diffusing and reflecting light received from the outside, a glaring phenomenon may be reduced, and accordingly, contrast of a screen displayed on the display panel 20 may be improved.

Also, the front cover 70 may reduce transmittance of incident external light or external light reflected from the substrate 40 and the gap G.

The front cover 70 according to one or more embodiments may include a material capable of reducing transmittance of light, to absorb at least one part of light transmitted toward the substrate 40 or light reflected from the substrate 40 and then traveling toward the first direction X.

While a plurality of substrates are manufactured, some of the substrates may have different colors due to a process reason in the manufacturing process. Accordingly, substrates having different unique colors may be tiled to constitute a single display panel.

As described above, the front cover 70 according to one or more embodiments may absorb at least one part of light reflected from the substrate 40 and transmitted to the outside, thereby raising a sense of unity of a screen displayed on the display panel 20.

That is, the front cover 70 may reduce color deviation generated during processes of the plurality of display modules 30A to 30P by lowering transmittance with respect to external light.

The front cover 70 may prevent external light entered the display panel 20 from the outside from being transmitted to the substrate 40, and additionally absorb a part of light entered the display panel 20 from the outside or a part of external light reflected from the substrate 40 and then transmitted to the outside of the display panel 20, thereby improving contrast of a screen that is displayed on the display panel 20. Such different optical actions may be respectively implemented by the plurality of layers described above.

That is, the front cover 70 may be positioned in front of the substrate 40 in the first direction X to improve contrast that may deteriorate by external light in a screen displayed on the display panel 20.

As described above, in the display module 30 according to one or more embodiments, the front cover 70 may extend to the outer location from the substrate 40 in the second direction Y.

Accordingly, a part of light that has entered the gap G formed between the plurality of display modules 30A to 30P may be blocked by at least one portion of the front cover 70 positioned in the gap G, and at least a part of external light that has entered the gap G or reflected in the gap G may be absorbed by the front cover 70 positioned in the gap G and thus be not transmitted to the outside. Accordingly, visibility of a seam that is formed in the gap G may deteriorate, and due to the deterioration of the visibility of the seam, a sense of unity of a screen that is displayed on the display panel 20 may be improved.

The side end 75 of the front cover 70 in the second direction Y may be positioned at an outer location than the edge 41e of the mounting surface 41 in the second direction Y, or in the gap G.

Accordingly, the front cover 70 may include a first area 71 positioned at the outer location than the edge 41e of the mounting surface 41 in the second direction Y or in the gap G, and a second area 72 positioned above the mounting surface 41.

The first area 71 and the second area 72 of the front cover 70 may be partitioned by the gap G in the second direction Y.

Because the first area 71 of the front cover 70 is positioned in the gap G, external light irradiated toward the gap G may be blocked by the first area 71 of the front cover 70 or light reflected in the gap G may be prevented from being irradiated to the outside. Accordingly, visibility of a seam which is a boundary between the plurality of display modules 30A to 30P and which may be formed by the gap G may be reduced, resulting in an improvement of a sense of unity of the display panel 20.

Because the front cover 70 extends to the outer location than the four edges 41e of the mounting surface 41 of the substrate 40, as described above, visibility of seams that may be formed at the edges of the plurality of display modules 30A to 30P may be reduced.

In the example of the first display module 30A and the second display module 30E, a first area 71A of a first front cover 70A extending from the first display module 30A may be positioned in a gap G formed between the first display module 30A and the second display module 30E.

In the gap G, neighboring side ends 75A and 75E of the front covers 70A and 70E of the first and second display modules 30A and 30E may be positioned.

Also, in the gap G, the side surfaces 45 and chamfer portions 49 of the first and second display modules 30A and 30E may be positioned.

A second area 72A of the first front cover 70A may be positioned above the mounting surface 41 of the first display module 30A.

A first area 71E of the second cover 70E extending from the second display module 30E may be positioned in the gap G formed between the first display module 30A and the second display module 30E, and a second area 72E of the second front cover 70E may be positioned above the mounting surface 41 of the second display module 30E.

That is, in the gap G formed between the first display module 30A and the second display module 30E, the first areas 71A and 71E of the first and second front covers 70A and 70E may be positioned side by side in the second direction Y.

Lengths in second direction Y of the first areas 71A and 71E of the first and second front covers 70A and 70E may be substantially smaller than or equal to half of a length of the gap G.

Accordingly, a sum of the lengths of the first areas 71A and 71E of the first and second front covers 70A and 70E arranged side by side in the second direction Y may substantially correspond to or be smaller than the length of the gap G.

According to one or more embodiments, upon a parallel arrangement in second direction Y of the first areas 71A and 71E of the first and second front covers 70A and 70E, a space may be formed between the side end 75A of the first cover 70A and the side end 75E of the second cover 70E.

However, the space may correspond to a very small value that is ignorable. Accordingly, the first display module 30A and the second display module 30E may be tiled without any substantially great space between the first area 71A of the first front cover 70A and the first area 71E of the second cover 70E.

The first area 71A of the first front cover 70A and the first area 71E of the second front cover 70E may be positioned in the gap G between the first display module 30A and the second display module 30E, as described above.

External light entered the display panel 20 may be diffused and reflected to the outside of the display panel 20 while being transmitted through the first areas 71A and 71E of the first and second front covers 70A and 70E, or a part of the external light may be absorbed in the first areas 71A and 71E. Accordingly, an amount of the external light arrived at the gap G may be reduced, which reduces visibility of a boundary between the first display module 30A and the second display module 30E, caused by the gap G.

Also, light reflected in the gap G and then traveling to the outside of the display panel 20 may be diffused and reflected to the outside of the display panel 20 while being transmitted through the first areas 71A and 71E of the first and second front covers 70A and 70E, or a part of the light may be absorbed in the first areas 71A and 71E. Accordingly, an amount of light transmitted to the outside of the display panel 20 may be reduced, which reduces visibility of a boundary between the first display module 30A and the second display module 30E, caused by the gap G.

That is, by reducing an amount of external light entering the gap G formed between the plurality of display modules 30A to 30P while absorbing at least one part of the external light reflected in the gap G, a sense of unity of a screen displayed on the display panel 20 may be improved.

Additionally, although a substrate 40A of the first display module 30A and a substrate 40E of the second display module 30E have different colors, at least one part of external light reflected from the substrates 40A and 40B may be absorbed in the first and second front covers 70A and 70E. Accordingly, unique colors of the substrates 40A and 40E may not be recognized from the outside, which improves a sense of unity of a screen displayed on the display panel 20.

The display module 30A may include the side cover 90 positioned below the front cover 70 in the direction in which the mounting surface 41 faces and provided on the side surface 45 of the substrate 40.

The side cover 90 may be positioned in a space defined by a lower surface 76 of the first area 71 of the front cover 70 in the first direction X and the side surface 45 of the substrate 40 in the second direction Y.

The side cover 90 may be in contact with the lower surface 76 of the first area 71, the side surface 45, and at least one portion of the metal plate 60. For example, the side cover 90 may be in contact with the entire of the lower surface 76 of the first area 71. Also, for example, the side cover 90 may cover the entire area of the side surface 45.

Also, the side cover 90 may cover all of a pair of chamfer portions 49 located in front and rear directions of the side surface 45 in the first direction X.

The side cover 90 may surround the entire of the chamber portion 49 formed between the mounting surface 41 and the side surface 45, as well as the side surface 45.

Because the side cover 90 surrounds the chamfer portion 49 formed between the mounting surface 41 and the side surface 45, the side cover 90 may fill the entire of a space that may be defined between the substrate 40 and the front cover 70.

Accordingly, the side cover 90 may prevent a foreign material or water from the outside from entering the space between the substrate 40 and the front cover 70.

Also, because the side cover 90 surrounds the chamfer portion 49 formed between the rear surface 43 and the side surface 45, the side cover 90 may fill the entire of a space that may be defined between the substrate 40 and the metal plate 60.

Accordingly, the side cover 90 may prevent a foreign material or water from the outside from entering the space between the substrate 40 and the metal plate 60.

The side cover 90 may be in contact with the lower surface 76 of the first area 71, the chamfer portion 49 of the substrate 40, and the side surface 45. Accordingly, the side cover 90 may support the lower surface 76 of the first area 71, the chamfer portion 49 of the substrate 40, and the side surface 45.

As described above, the substrate 40 may be bonded with the front cover 70 by the front cover 70, and the side cover 90 may reinforce an adhesive property between the substrate 40 and the front cover 70. Accordingly, the side cover 90 may prevent the front cover 70 from departing from the substrate 40.

That is, the side cover 90 may raise reliability of the display module 30A.

Also, the substrate 40 may be bonded with the metal plate 60 by the rear adhesive layer 61, and the side cover 90 may reinforce an adhesive property between the metal plate 60 and the substrate 40. Accordingly, the side cover 90 may prevent the metal plate 60 from departing from the substrate 40.

As described above, the side surface 45 of the substrate 40 may correspond to the four edges 41e of the mounting surface 41, and the first area 71 of the front cover 70 may extend up to the outer location than the four edges 41e of the mounting surface 41 in the second direction Y and the third direction Z in which the mounting surface 41 extends.

The side cover 90 may surround the lower surface 76 of the first area 71 and the side surface 45 corresponding to the four edges 41e of the mounting surface 41, along the four edges 41e of the mounting surface 41.

That is, the side cover 90 may seal an entire edge of a portion at which the substrate 40 is bonded with the front cover 70.

The side cover 90 may cover the side surface 54 and the lower surface 76 of the first area 71 in all directions that are orthogonal to the first direction X.

Accordingly, a coupling force between the front cover 70 and the substrate 40 may be improved, and the front cover 70 and the side surface 45 of the substrate 40 may be protected from an external force.

Also, a foreign material or water from the outside may be prevented from entering between the substrate 40 and the front cover 70, as described above. In addition, upon formation of a gap between the substrate 40 and the front cover 70 due to a reason of adhesion, outside water or a foreign material may be prevented from entering the gap.

Because the side cover 90 surrounds all the four edges E of the substrate 40 along the side surface 45 of the substrate 40, an effect of sealing the substrate 40, the front cover 70, and the metal plate 60 may be obtained.

Accordingly, the side cover 90 may prevent a foreign material or water from entering between the substrate 40 and the front cover 70 in all directions in which the foreign material or water may enter the substrate 40.

Upon exposure of the lower surface 76 of the first area 71 to the outside, a foreign material moving in the outside may be adhered to the lower surface 76 of the first area 71 or the adhesive layer 110.

Upon an arrangement of the plurality of display modules 30A to 30P in a state in which a foreign material is adhered to the lower surface 76 of the first area 71, visibility of a seam generated between the plurality of display modules 30A to 30P may be raised by the foreign material adhered to the lower surface 76 of the first area 71.

However, because the display module 30A according to one or more embodiments includes the side cover 90, and the side cover 90 covers the lower surface 76 of the first area 71, the display module 30A may prevent a foreign material from being adhered to the lower surface 76 of the first area 71.

Accordingly, visibility of a seam generated between the plurality of display modules 30A to 30P due to a foreign material adhered to the front cover 70 upon an arrangement of the plurality of display modules 30A to 30P may be reduced.

Also, current may flow to a plurality of electronic components mounted on the substrate 40 by an electrostatic discharge which may occur on the display modules 30A to 30P to damage the electronic components, and the side cover 90 may seal the substrate 40 from the outside and thus block charges generated by an electrostatic discharge from entering the substrate 40, to prevent the electronic components from being damaged.

That is, because the substrate 40 is sealed by the front cover 70 and the side cover 90, charges generated by an electrostatic discharge may be prevented from passing through the front cover 70 and the side cover 90 and thus flowing to the substrate 40. Also, charges flowing on the front cover 70 and the side cover 90 may be guided to the metal plate 60 being in contact with the side cover 90, thereby providing a path for current generated by an electrostatic discharge. Accordingly, an electrostatic discharge (ESD) withstanding voltage of the electronic components mounted on the substrate 40 may be improved.

As described above, the display module 30A may be positioned below the front cover 70 in the direction in which the mounting surface 41 faces. That is, the side cover 90 may not be positioned above the lower surface 76 in the first direction X.

A most front surface 92 of the side cover 90 in the first direction X may be in contact with the lower surface 76 of the first area 71, and may not be positioned before the lower surface 76 of the first area 71 in the first direction X. The reason may be not to locate the side cover 90 on a traveling path of light emitted from the plurality of inorganic light-emitting elements 50.

In a case in which at least one portion of the side cover 90 is positioned before the lower surface 76 or the front cover 70 in the first direction X, the at least one portion of the side cover 90 may be positioned on a traveling path of light traveling forward through the front cover 70.

That is, the side cover 90 may absorb or diffuse and reflect a part of traveling light to distort an area of an image displayed on the display panel 20.

However, because the side cover 90 according to one or more embodiments is positioned behind the front cover 70 in the first direction X, the side cover 90 may not limit traveling of light emitted from the plurality of light-emitting devices 50, thereby improving image quality of the display panel 20.

The side end 75 of the front cover 70 in the second direction Y and a side end 91 of the side cover 90 in the second direction Y may be substantially aligned in the first direction X.

The reason may be because the front cover 70 and the side cover 90 are cut simultaneously in a process of manufacturing the display module 30A. Also, an additional conductive layer 100 (also 100A and 100E) may be bonded on the side end 75 of the front cover 70 and the side end 91 of the side cover 90, substantially aligned in the first direction X.

That is, a space that may be formed between the plurality of display modules 30A to 30P upon an arrangement of the plurality of display modules 30A to 30P may be minimized, and visibility of a seam, which is caused by the space between the plurality of display modules 30A to 30P, may be minimized.

The side cover 90 may include a light absorbing material. For example, the side cover 90 may be formed of an opaque or translucent material.

Also, the side cover 90 may include a photosensitive material. For example, the side cover 90 may be formed of a photosensitive OCR. The photosensitive material may change physical properties to show a dark color by receiving external light, such as ultraviolet (UV) light, having a wavelength that is different from that of visible light.

Accordingly, by irradiating UV light to the side cover 90 during a manufacturing process to color the side cover 90 with a dark color, the side cover 90 may be provided as a light absorbing member.

The side cover 90 may have a dark color. The side cover 90 may have a darker color than the front cover 70. Accordingly, light entered the side cover 90 may be absorbed in the side cover 90 without being reflected, by the light absorbing member of the side cover 90.

The side cover 90 may be positioned in the gap G formed between the plurality of display modules 30A to 30P, together with the first area 71 of the front cover 70, upon an arrangement of the plurality of display modules 30A to 30P.

Accordingly, by absorbing light entered the gap G, an amount of light reflected and then emitted to the outside among the light entered the gap G may be minimized. Therefore, visibility of a seam formed by the gap G formed between the plurality of display modules 30A to 30P may be reduced.

In the example of the first display module 30A and the second display module 30E, the first side cover 90A of the first display module 30A and the second side cover 90E of the second display module 30E may be positioned in the gap G formed between the first display module 30A and the second display module 30E, together with the first area 71A of the first cover 70A and the first area 71E of the second cover 70E.

In the gap G, neighboring side ends 90A and 90E of the side covers 90A and 90E may be positioned together with the neighboring side ends 75A and 75E of the front covers 70A and 70E of the first and second display modules 30A and 30E.

The neighboring side ends 75A and 75E of the front covers 70A and 70E and the neighboring side ends 90A and 90E of the side covers 90A and 90E may be opposite to each other. For example, the neighboring side ends 75A and 75E of the front covers 70A and 70E and the neighboring side ends 90A and 90E of the side covers 90A and 90E may be positioned in parallel to each other.

That is, in the gap G formed between the first display module 30A and the second display modules 30E, the first areas 71A and 71E of the first and second front covers 70A and 70E and the first and second side covers 90A and 90E may be positioned in parallel in the second direction Y.

Lengths in second direction Y of the first and second side covers 90A and 90E may be substantially smaller than or equal to half of the length of the gap G to correspond to the first areas 71A and 71E of the first and second front covers 70A and 70E.

In the gap G between the first display module 30A and the second display module 30E, the first area 71A of the first front cover 70A and the first area 71E of the second front cover 70E may be positioned, and the first and second side covers 90A and 90E may be positioned behind the first areas 71A and 71E in the first direction X.

External light entered the display panel 20 may be diffused and reflected to the outside of the display panel 20 by being transmitted through the first areas 71A and 71E of the first and second front covers 70A and 70E, or a part of the external light may be absorbed in the first areas 71A and 71E of the first and second front covers 70A and 70E, as described above. Accordingly, an amount of light arrived at the gap G may be reduced.

In addition, light arrived at the gap G may be absorbed in the first and second side covers 90A and 90E positioned in the gap G, and accordingly, visibility of a boundary between the first display module 30A and the second display module 30E may be reduced.

That is, by reducing an amount of external light entering the gap G formed between the plurality of display modules 30A to 30P and additionally absorbing light arrived at the gap G, a sense of unity of a screen of the display panel 20 may be improved.

In addition, light reflected from the first and second side covers 90A and 90B without being absorbed in the first and second side covers 90A and 90E and then traveling to the outside of the display panel 20 may be diffused and reflected to the outside of the display panel 20 by being transmitted through the first areas 71A and 71E of the first and second front covers 70A and 70E, or a part of the light may be absorbed in the first areas 71A and 71E. Accordingly, an amount of light transmitted to the outside of the display panel 20 may be reduced, and thus, visibility of the boundary between the first display module 30A and the second display module 30E, caused by the gap G, may be reduced.

Because the side cover 90 is positioned in the gap G formed between the plurality of display modules 30A to 30P upon an arrangement of the plurality of display modules 30A to 30P, as described above, the side cover 90 may absorb light arrived at the gap G to reduce visibility of a seam, caused by the gap G.

In the above-described example, the front cover 70 may diffuse and reflect, absorb, or circularly polarize a part of light entered the display panel 20, or change a reflection direction of the part of the light, thereby reducing an amount of light that arrives at the substrate 40, although not limited thereto.

However, the front cover 70 may be formed of a transparent material to transmit light without any deformation. In this case, visibility of the boundary between the plurality of display modules 30A to 30P, caused by the gap G, may be reduced by the side cover 90 positioned between the plurality of display modules 30A to 30P.

Because the side cover 90 is formed of a light absorbing material, as described above, a part of light emitted from the plurality of inorganic light-emitting elements 50 may be absorbed in the side cover 90 in a case in which at least one portion of the side cover 90 is positioned before the front cover 70 in the first direction X. Accordingly, an area of a screen displayed on the display panel 20 may appear dark.

However, because the side cover 90 according to one or more embodiments is positioned below the front cover 70 in the first direction X, for example, below the lower surface 76 of the first area 71, the side cover 90 may not absorb light emitted from the plurality of inorganic light-emitting elements 50, and accordingly, brightness of an image displayed on the display panel 20 may be uniform.

As shown in FIGS. 8 and 9, the front cover 70 may extend up to the outer location than the substrate 40 in the third direction Z. The front cover 70 may extend up to the outer location than the side surface 45 and the chamfer portion 49 in the third direction Z.

The side end 75 of the front cover 70 in the third direction Z may be positioned at the outer location than the edge 41e of the mounting surface 41 in the third direction Z, or in the gap G.

The first area 71 and the second area 72 of the front cover 70 described above may be partitioned by the gap G even in the third direction Z.

In an example of the first display modules 30A and the third display module 30B, the first area 71A of the first front cover 70A extending from the first display module 30A may be positioned in a gap G formed between the first display module 30A and the third display module 30B.

In the gap G, neighboring side ends 75A and 75B of the front covers 70A and 70B of the first and third display modules 30A and 30B may be positioned.

Also, the side surfaces 45 and chamfer portions 49 of the first and third display modules 30A and 30B may be positioned in the gap G.

A first area 71B of a third front cover 70B extending from the third display module 30B may be positioned in the gap G formed between the first display module 30A and the third display module 30B, and a second area 72B of the third front cover 70B may be positioned above the mounting surface 41 of the third display module 30B.

That is, in the gap G between the first display module 30A and the third display module 30B, the first areas 71A and 71B of the first and third front covers 70A and 70B may be positioned side by side in the third direction Z.

External light entered the display panel 20 may be diffused and reflected to the outside of the display panel 20 by being transmitted through the first areas 71A and 71B of the first and third front covers 70A and 70B, or a part of the external light may be absorbed in the first areas 71A and 71B. Accordingly, an amount of light arrived at the gap G may be reduced, and visibility of a boundary between the first display module 30A and the third display module 30B, caused by the gap G, may be reduced.

Also, light reflected in the gap G and then traveling to the outside of the display panel 20 may be diffused and reflected to the outside of the display panel 20 by being transmitted through the first areas 71A and 71B of the first and third front covers 70A and 70B, or a part of the light may be absorbed in the first areas 71A and 71B. Accordingly, an amount of light transmitted to the outside of the display panel 20 may be reduced, and visibility of the boundary between the first display module 30A and the third display module 30B, caused by the gap G, may be reduced.

As described above, the side cover 90 may be positioned in a space formed in the side surface 45 of the substrate 40 in the second direction Y and the third direction Z.

On the side surface 45 of the substrate 40 extending in the third direction Z, the side wiring 46 may be positioned. Accordingly, the side cover 90 provided on the side surface 45 extending in the third direction Z may surround the side wiring 46, as well as the side surface 45 and the chamfer portion 49. Accordingly, the side cover 90 may protect the side wiring 46 from an external force, and prevent a foreign material or water from entering the side wiring 46.

That is, the side cover 90 may surround the side wiring 46 extending along the side surface 45 in the third direction Z by surrounding the lower surface 76 of the first area 71 and the side surface 45 corresponding to the four edges 41e of the mounting surface 41 along the four edges 41e of the mounting surface 41.

Accordingly, binding between the front cover 70 and the substrate 40 may be improved, and the front cover 70, the side surface 45 of the substrate 40, and the side wiring 46 may be protected from an external force.

The side end 70 of the front cover 70 in the third direction Z and the side end 91 of the side cover 90 in the third direction Z may be aligned in the first direction X. The side end 70 of the front cover 70 and the side end 91 of the side cover 90 may be aligned in a direction that is in parallel to the first direction X.

In the example of the first display module 30A and the third display module 30B, the first side cover 90A of the first display module 30A and the third side cover 90B of the third display module 30B may be positioned in the gap G formed between the first display module 30A and the third display module 30B, together with the first area 71A of the first front cover 70A and the third area 71B of the third front cover 70B.

In the gap G, neighboring side ends 91A and 91B of the side covers 90A and 90B may be positioned together with the neighboring side ends 75A and 75B of the first and third front covers 70A and 70B of the first and third display modules 30A and 30B.

The neighboring side ends 75A and 75B of the front covers 70A and 70B and the neighboring side ends 91A and 91B of the side covers 90A and 90B may be opposite to each other.

For example, the neighboring side ends 75A and 75B of the front covers 70A and 70B and the neighboring side ends 90A and 90B of the side covers 90A and 90B may be positioned in parallel to each other.

That is, in the gap G formed between the first display module 30A and the third display module 30B, the first areas 71A and 71B of the first and third front covers 70A and 70B and the first and third side covers 90A and 90B may be positioned side by side in the third direction Z.

Because the side end 75 of the front cover 70 and the side end 91 of the side cover 90 in the third direction Z are aligned in the first direction X and the additional conductive layer 100 is bonded to the side end 75 of the front cover 70 and the side end 91 of the side cover 90 in the third direction Z, a space that may be formed between the first and third display modules 30A and 30B upon an arrangement of the first and third display modules 30A and 30B may be minimized.

In the gap G formed between the first display module 30A and the third display module 30B, the first areas 71A and 71B of the first and third front covers 70A and 70B and the first and third side covers 90A and 90B may be arranged side by side in the third direction Z.

In the gap G formed between the first display module 30A and the third display module 30B, the first area 71A of the first front cover 70A and the first area 71B of the third front cover 70B may be arranged, and the first and third side covers 90A and 90B may be arranged behind the first areas 71A and 71B in the first direction X.

As described above, external light entered the display panel 20 may be diffused and reflected to the outside of the display panel 20 by being transmitted through the first areas 71A and 71B of the first and third front covers 70A and 70B, or a part of the external light may be absorbed in the first areas 71A and 71B. Accordingly, an amount of light arrived at the gap G may be reduced.

In addition, light arrived at the gap G may be absorbed in the first and third side covers 90A and 90B positioned in the gap G, and accordingly, visibility of the boundary between the first display module 30A and the third display module 30B may be reduced.

Light reflected from the first and third side covers 90A and 90B and then traveling to the outside of the display panel 20 without being absorbed in the first and third side covers 90A and 90B may be diffused and reflected to the outside of the display panel 20 by being transmitted through the first areas 71A and 71B of the first and third front covers 70A and 70B, or a part of the light may be absorbed in the first areas 71A and 71B. Accordingly, an amount of light transmitted to the outside of the display panel 20 may be reduced, and visibility of the boundary between the first display module 30A and the second display module 30B, caused by the gap G, may be reduced.

The side cover 90 may be applied with a preset amount by a dispenser in a manufacturing process. The applied side cover 90 may be hardened through a follow-up task. The side cover 90 may be formed of, for example, a nonconductive black resin.

The side cover 90 may cover all of a rear surface of the front cover 70, the side surface 45 of the substrate 40, the chamfer portion 49 formed between the mounting surface 41 and the side surface 45, and the chamfer portion 49 formed between the side surface 45 and the rear surface 43.

Also, an area of the anisotropic conductive layer 47, positioned at an outer location than the mounting surface 41, and a side end 47S of the anisotropic conductive layer 47 may be covered by the applied side cover 90.

A task of dispensing the side cover 90 may be performed on all the four edges of the substrate 40. Accordingly, the side cover 90 may be dispensed to cover the entire of the side surface 45 of the substrate 40. Also, the entire of the area of the anisotropic conductive layer 47, positioned at the outer location than the mounting surface 41, may be covered by the side cover 90.

As the side cover 90 is hardened, the side cover 90 may be in contact with the rear surface of the front cover 70 in the first direction X, the side surface 45 of the substrate 40, the chamfer portion 49 formed between the side surface 45 and the mounting surface 41, and an area of the anisotropic conductive layer 47, positioned outside the mounting surface 41.

The side cover 90 may include a photosensitive material. In this case, by irradiating ultraviolet light (UX) or the like onto the side cover 90, as a follow-up task, the side cover 90 may be colored with a dark color. However, the side cover 90 may be formed of a translucent or opaque material without including any photosensitive material. In this case, a process of coloring the side cover 90 may be not required.

As described above, the side wiring 46 may be positioned on the side surface 45 of the substrate 40 in the third direction Z. The side wiring 46 may be prevented from being exposed to the outside by the side cover 90.

In addition, a sealing member 95 for sealing the side wiring 46 may be formed to prevent the side wiring 46 from being exposed to the outside. The sealing member 95 may be positioned to seal a portion of the side wiring 46 connected to the rear wiring layer 43b.

Although the side cover 90 covers the side surface 45 of the substrate 40, as described above, the sealing member 95 may prevent a portion of the side wiring 46 connected to the rear wiring layer 43b from being exposed to the outside in a case in which the side cover 90 does not cover the portion of the side wiring 46 due to an error that occurs in a process of dispensing the side cover 90.

Because the portion of the side wiring 46 connected to the rear wiring layer 43b is positioned at an edge of the rear surface 43 of the substrate 40, the portion may not be covered by the side cover 90 dispensed.

Accordingly, by additionally dispensing the sealing member 95 onto edges of the rear surface 43 of the substrate 40, the side wiring 46 may be protected from the outside.

However, in a case in which the side cover 90 extends in the first direction X and covers a side surface of the display module 30 in such a way as to cover the side surface 45 and at least one portion of a side surface of the metal plate 60, the process of dispensing the sealing member 95 may be omitted, and the side cover 90 may cover the portion of the side wiring 46 connected to the rear wiring layer 43b.

For example, the side cover 90 may be dispensed to cover the edges of the rear surface 43, as well as the side surface 45, and in this case, the sealing member 95 may not be additionally dispensed.

The side cover 90 may cover, as shown in FIGS. 7 and 9, an outer area in the third direction Z from the side surface 45 of the substrate 40, while covering an outer area in the second direction Y from the side surface 45.

For example, the side cover 90 may surround all the four edges E of the substrate 40.

Accordingly, the mounting surface 41 which is the front surface of the substrate 40 may be covered by the front cover 70, the rear surface 43 of the substrate 40 may be covered by the metal plate 60 or by the metal plate 60 and the sealing member 95, and the side surface 45 and the chamfer portion 49 of the substrate 40 may be covered by the side cover 90.

The side cover 90 may extend from an upper portion of the metal plate 60 up to the lower surface 76 of the front cover 70 in the first direction X, or the side cover 90 may cover the entire side surface of the display module 30 together with the sealing member 95, thereby completely sealing the substrate 40 from the outside.

The front cover 70 may be formed of a nonconductive material through which no charges are transmitted.

The side cover 90 may be formed of a nonconductive material through which no charges are transmitted.

The sealing member 95 may be formed of a nonconductive material through which no charges are transmitted.

Because the front cover 70, the side cover 90, and the sealing member 95 are formed of a nonconductive material, a major portion of current applied to the front cover 70 or the side cover 90 may flow on the front cover 70 and the side cover 90 without being transmitted through the front cover 70 and the side cover 90.

Also, the metal plate 60 may be formed of a material having great capacitance, and function as a ground component. Accordingly, upon application of current to the metal plate 60, the metal plate 60 may be maintained at a constant potential, and the current applied to the metal plate 60 may be absorbed in the metal plate 60 without flowing to the substrate 40 through the metal plate 60.

That is, in the display apparatus 1, the entire of the side wiring 46 of the substrate 40 may be surrounded by the side cover 90 and the sealing member 95, and accordingly, the side wiring 46 may be sealed without being exposed to the outside. Therefore, although an electrostatic discharge occurs at the side surface 45 of the substrate 40, no current may enter the side wiring 46 by the side cover 90. In a process of manufacturing a display apparatus by implementing a display panel with display modules, a plurality of display modules may be tiled to form the display panel. In a process of forming the display panel with the display modules, current generated by an electrostatic discharge while the display modules are manufactured and delivered may enter the insides of the display modules to damage electronic components installed inside the display modules.

During a process of manufacturing the display module 30, a defect may be generated, and in this case, the side wiring 46 or the anisotropic conductive layer 47 extending along the side surface 45 of the substrate 40 may be exposed to the outside, a space may be made due to a poor contact between the front cover 70 and the substrate 40, or an inside space may be made in a process of applying and hardening the side cover 90. In this case, according to an electrostatic discharge, current may enter the space made by the poor contact, the anisotropic conductive layer 47, or the side wiring 46 to damage the electronic components positioned on the substrate.

To prevent current generated by an electrostatic discharge from entering the display module 30 to damage the electronic components installed inside the display module 30 in a process before the display module 30 is coupled to the frame 15 to be assembled into the display apparatus 1, the display module 30 may include the front cover 70, the side cover 90, the sealing member 95, and the metal plate 60 to absorb an electrical impact.

Accordingly, each of the display modules 30A to 30P may independently include a component for blocking current generated by an electrostatic discharge from entering the components mounted on the substrate 40, and the current generated by the electrostatic discharge may be easily guided to the metal plate 60 which is a ground component along the front cover 70, the sealing member 95, and the side cover 90 sealing the substrate 40 on each of the display modules 30A to 30P without entering the components mounted on the substrate 40.

However, the electronic components may be damaged due to a defect that occurs in the process of manufacturing the display modules 30A to 30P, as described above. Current generated by an electrostatic discharge may enter the plurality of electronic components mounted on the substrate 40 in the first direction X to damage the electronic components.

To prevent this, the display apparatus 1 according to one or more embodiments may include an additional conductive layer 100. The above-described anisotropic conductive layer 47 may be a first conductive layer 47, and the additional conductive layer 100 may be a second conductive layer 100. Also, the second conductive layer 100 may be a transparent conductive layer 100 including a transparent conductive material.

The second conductive layer 100 may be positioned in front of the substrate 40 (for example, in the first direction X from the substrate 40). The second conductive layer 100 may be positioned between the front cover 70 and the substrate 40. For example, the second conductive layer 100 may be inserted between the front cover 70 and the adhesive layer 110 adhering the front cover 70 to the substrate 40.

The second conductive layer 100 may absorb current generated by an electrostatic discharge in the first direction X from the substrate to prevent static electricity from entering the plurality of electronic components mounted on the substrate 40 although the display modules 30A to 30P are not completely sealed by manufacturing defects.

Because the display modules 30A to 30P have the same configuration, only the first display module 30A will be described as a representative, below. The second conductive layer 100 may extend in the second direction Y and the third direction Z, as shown in FIGS. 7 to 9.

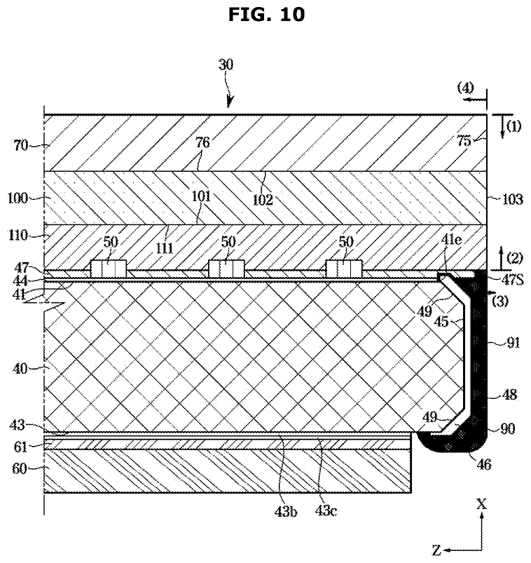

FIG. 10 shows a display module in the display apparatus of FIG. 1.

The side wiring 46, a coating portion 48, and the side cover 90 shown in FIGS. 7 to 9 may be only examples, and the side wiring 46, the coating portion 48, and the side cover 90 may include various shapes. Accordingly, the side wiring 46, the coating portion 48, and the side cover 90 may be formed as shown in FIG. 10. For example, the side wiring 46 may be shown enlarged.

Referring to FIG. 10, the second conductive layer 100 may be positioned behind the front cover 70 (1). Accordingly, the second conductive layer 100 may be protected by the front cover against physical contacts or scratches from the outside of the display module 30.

The second conductive layer 100 may be positioned in front of the adhesive layer 110 that adheres the front cover 70 to the substrate 40 (2). Because the second conductive layer 100 has higher electric conductivity than the adhesive layer 110, as will be described below, the second conductive layer 100 may absorb current generated by an electrostatic discharge in the front direction from the inorganic light-emitting elements 50 to prevent static electricity from flowing to components such as the inorganic light-emitting elements 50 via the adhesive layer 110.

The second conductive layer 100 may further extend in the side direction than the side wiring 46 (3). Accordingly, the second conductive layer 100 may first absorb current generated by an electrostatic discharge in the first direction X from the substrate 40 to prevent the current from flowing to the side wiring 46 along the side surface of the substrate 40.

Also, the second conductive layer 100 may not further extend in the side direction than the front cover 70 (4). For example, a third surface 103 of the second conductive layer 100 may neither further protrude nor extend than the side end 75 of the front cover 70. Accordingly, the second conductive layer 100 may be protected by the front cover against external contacts or scratches that may occur in the side direction of the display module 30.

However, an arrangement or insertion location of the second conductive layer 100 is not limited to the above-described example, and the second conductive layer 100 may be inserted into various locations to absorb static electricity flowing to the substrate 40.

For example, the second conductive layer 100 may be positioned between the front cover 70 and the adhesive layer 110.

The second conductive layer 100 may include a first surface 101, a second surface 102, and the third surface 103. The first surface 101 may be in contact with the adhesive layer 110. For example, the first surface 101 may be in contact with an upper surface 111 of the adhesive layer 110.

The second surface 102 may be a side of the second conductive layer 100 toward the first direction X, and may be in contact with the front cover 70. For example, the second surface 102 may be in contact with the lower surface 76 of the front cover 70.

The third surface 103 may be provided at a side end of the display module 30. The third surface 103 may be a side surface 103. In FIGS. 7 to 9, the side surface of the second conductive layer 100 is shown to be continuous, although not limited thereto, second conductive layers 100 may be spaced from each other in the third direction Z in the display module 30. The third surface 103 of the second conductive layer 100 may be exposed to the outside of the display module 30 to discharge absorbed ESD current to the outside of the display module 30.

The second conductive layer 100 may be formed of a material having higher conductivity than the side cover 90 and the sealing member 95. The second conductive layer 100 may be formed of, for example, a metal material. However, the material of the second conductive layer 100 is not limited to this, and include a carbon material.

Also, the second conductive layer 100 may include a transparent conductive oxide (TCO). For example, the second conductive layer 100 may include an indium tin oxide (ITO) film.

The second conductive layer 100 may have higher electrical conductivity than the front cover 70 and the adhesive layer 110 provided at the both sides. Accordingly, current generated by an electrostatic discharge may flow to the second conductive layer 100, not to the front cover 70 or the adhesive layer 110. As a result, the current generated by the electrostatic discharge may be absorbed in the second conductive layer 100 without flowing to the substrate 40 or the inorganic light-emitting elements 50.

As a result, according to one or more embodiments, the display apparatus 1 capable of blocking ESD may be provided.

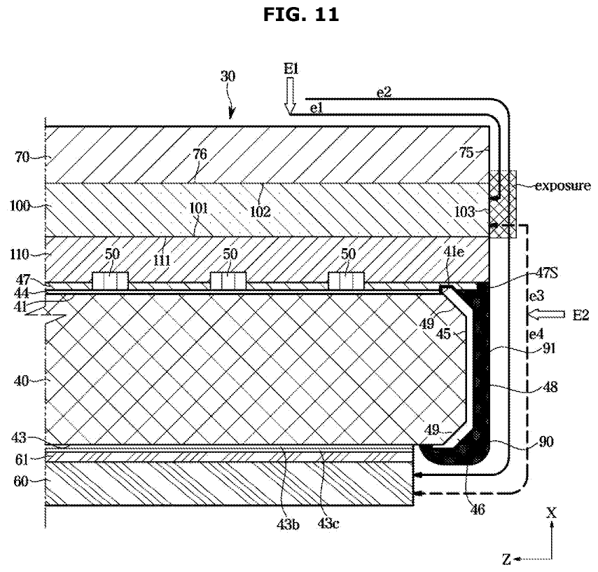

FIG. 11 schematically shows an ESD flow at a display module in the display apparatus according to one or more embodiments. For example, FIG. 11 schematically shows an ESD flow of some components in the display apparatus of FIG. 10. Also, in FIG. 11, the transparent conductive layer and the adhesive layer are exaggeratedly shown for description.

Referring to FIG. 11, the second conductive layer 100 may be exposed to the outside of the display module. For example, the third surface of the second conductive layer 100 may be exposed. Because the second conductive layer 100 is exposed, current that has entered the second conductive layer 100 may flow to the outside of the display module 30 without damaging the substrate 40 or the inorganic light-emitting elements 50.

Current e1 generated by an electrostatic discharge E1 on the front cover 70 may not enter the substrate 40 by failing to be transmitted through the front cover 70 and thus, the current e1 may flow on the front cover 70 to enter the second conductive layer 100.

The second conductive layer 100 may provide a path of current along which the current e1 generated by an electrostatic discharge E1 on the front cover 70 flows to the outside of the display module 30, which is a ground. In other words, the second conductive layer 100 may guide charges generated by an electrostatic discharge to flow to the ground.

Alternatively, another current e2 generated by an electrostatic discharge E1 on the front cover 70 may not enter the substrate 40 by failing to be transmitted through the front cover 70, and thus, the current e2 may bypass a side of the display module 30 to flow to the metal plate 60.

Also, current e3 and e4 generated by an electrostatic discharge E2 on the side cover 90 may not enter the substrate 40 by failing to be transmitted through the side cover 90, and thus, the current e3 and e4 may flow to the second conductive layer 100 and/or the metal plate 60.

All of the current e1 and e2 generated by an electrostatic discharge E1 on the front cover 70 or the current e3 and e4 generated by an electrostatic discharge E2 on the side cover 90 as described above may not flow to the second conductive layer 100, and at least a part of the current e1 and e2 and current e3 and e4 may remain on the front cover 70 or the side cover 90 and be transmitted through the front cover 70 and the side cover 90 to enter the substrate 40.

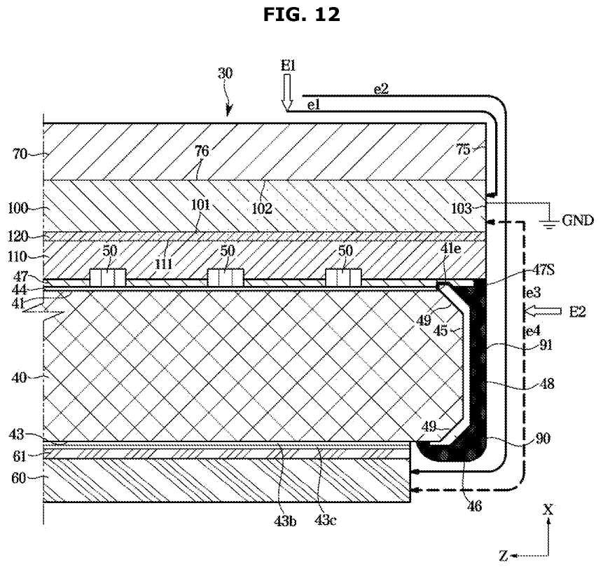

However, because a major part of the current e1 and e2 generated by an electrostatic discharge E1 on the front cover 70 or the current e3 and e4 generated by an electrostatic discharge E2 on the side cover 90 flows to the outside of the display module 30 or the ground (see FIG. 12) through the second conductive layer 100 having high conductivity, an ESD withstanding voltage of the electronic components mounted on the substrate 40 may be improved although some of the current e1 and e2 flows to the substrate 40.

Also, as described above, even though sealing between the front cover 70 and the side cover 90 is not perfect due to a defect occurred in the process of manufacturing the display modules 30A to 30P, current generated by an electrostatic discharge on the front cover 70 or the side cover 90 may be induced to the second conductive layer 100 having high conductivity to improve an ESD withstanding voltage of the electronic components mounted on the substrate 40.

In addition, static current transferred to the metal plate 60 may be discharged to an external ground through a component, such as a bridge board or a cable, for example, being in contact with the metal plate 60.

Accordingly, the display apparatus may minimize damage to the substrate 40 or the inorganic light-emitting elements 50 by ESD. Also, the above configurations may not be applied differently depending on long sides or short sides of the display module 30, and the display apparatus may not require an additional coating. In addition, because there is no additional component at the side end of the display module 30, visibility of seams may be improved.

As a result, according to one or more embodiments, the display apparatus 1 capable of blocking ESD while improving visibility of seams may be provided.

FIG. 12 schematically shows an ESD flow at a display module in the display apparatus according to one or more embodiments.

Referring to FIG. 12, the display module 30 may further include an insulating layer 120. The insulating layer 120 may be adjacent to the second conductive layer 100. For example, the insulating layer 120 may be positioned between the adhesive layer 110 and the second conductive layer 100.

The insulating layer 120 may include a first surface 121 and a second surface 122. The first surface 121 of the insulating layer 120 may be in contact with the upper surface 111 of the adhesive layer 110. The second surface 122 of the insulating layer 120 may be in contact with the first surface 101 of the second conductive layer 100.

The insulating layer 120 may prevent current el and e3 that has flowed to the second conductive layer 100 from flowing to the anisotropic conductive layer and the inorganic light-emitting elements 50.

The second conductive layer 100 may be grounded to the outside of the display module 30. For example, the second conductive layer 100 may be connected to a ground GND provided outside the display module 30 through the third surface 103. However, the second conductive layer 100 may be grounded through the first surface 101 or the second surface 102. Because the second conductive layer 100 is grounded to the outside of the display module 30, current entered the second conductive layer 100 may flow to the outside of the display module 30 without damaging the substrate 40 or the inorganic light-emitting elements 50.

Upon generation of current e1 by an electrostatic discharge E1 on the front cover 70, the current e1 may flow on the front cover 70 and flow to the second conductive layer 100. Also, upon generation of current e2(e3?) by an electrostatic discharge E2 on the side cover 70, the current e3 may not enter the substrate 40 by failing to be transmitted through the side cover 90 and thus flow to the second conductive layer 100.

Because the second conductive layer 100 is connected to the ground GND outside the display module 30, the current el and e3 entered the second conductive layer 100 may flow to the ground GND outside the display module 30.

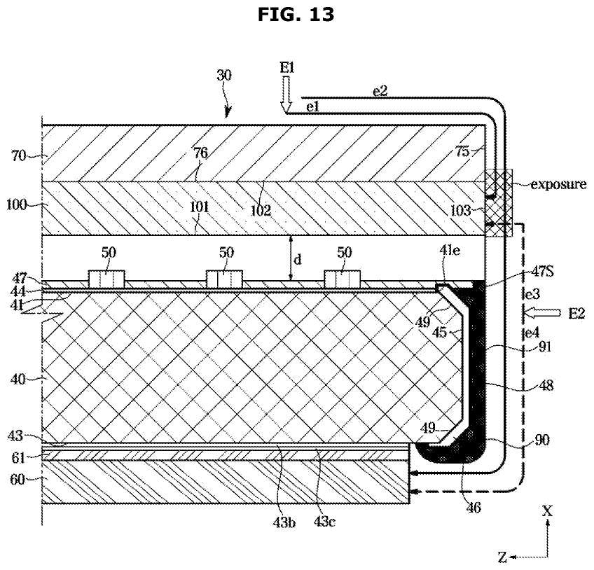

FIG. 13 schematically shows an ESD flow at a display module in the display apparatus according to one or more embodiments.

Referring to FIG. 13, the second conductive layer 100 may be provided toward the front cover 70. For example, the second conductive layer 100 may be adhered or bonded to the lower surface 76 of the front cover 70. The second conductive layer 100 may be spaced a preset distance d from the anisotropic conductive layer 47 or the inorganic light-emitting elements 50. Accordingly, current generated by an electrostatic discharge may not flow to the anisotropic conductive layer 47 or the inorganic light-emitting elements 50 although the current flows to the second conductive layer 100. As a result, it may be possible to prevent the electronic components mounted on the substrate 40 from being damaged due to current el and e3 flowing to the second conductive layer 100 among current generated by an electrostatic discharge. Herein, the front cover may be fixed by the frame 15.

The second conductive layer 100 may be exposed to the outside of the display module 30. Because the second conductive layer 100 is exposed, current entered the second conductive layer 100 may flow to the outside of the display module 30 without damaging the substrate 40 or the inorganic light-emitting elements 50.

As described above, current e1 and e3 which has generated by an electrostatic discharge E1 and E2 and flowed to the second conductive layer 100 may flow to the outside of the display module 30.

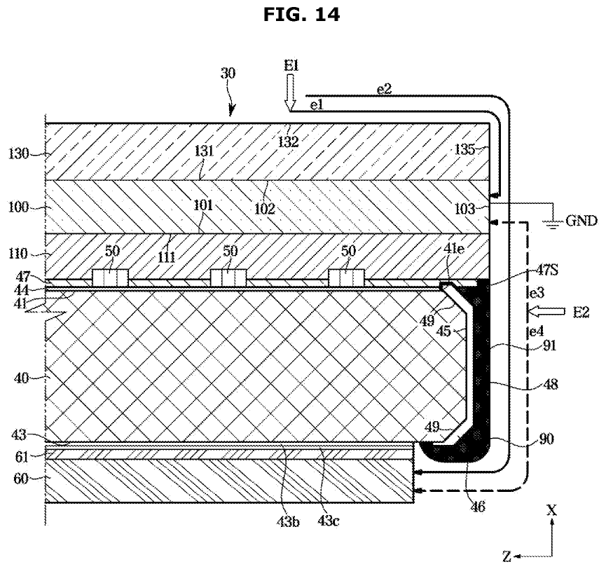

FIG. 14 schematically shows an ESD flow at a display module in the display apparatus according to one or more embodiments.

Referring to FIG. 14, the display apparatus according to one or more embodiments may further include an optical sheet 130. The optical sheet 130 may be provided in front of the inorganic light-emitting elements 50. The optical sheet 130 may refract and/or scatter light emitted from the inorganic light-emitting elements 50. Also, the optical sheet may improve brightness of light and brightness uniformity.

The optical sheet 130 may include a first surface 131, a second surface 132, and a side end 135. The first surface 131 may be in contact with the second surface 102 of the second conductive layer 100. The second surface 132 may be toward the front direction. The front cover 70 may be positioned in front of the optical sheet 130. The side surface 130 of the second conductive layer 100 may not further extend in the side direction than the optical sheet 130. The third surface 103 of the second conductive layer 100 may neither further protrude nor extend than the side end 135 of the optical sheet 130.

As described above, although current e1, e2, e3, and e4 is generated by an electrostatic discharge E1 and E2, the current e1, e2, e3, and e4 may flow to the second conductive layer 100 or the metal plate 60. The current el and e3 flowed to the second conductive layer 100 may flow to the ground GND and be discharged to the outside of the display module 30.

Accordingly, the display apparatus 1 may minimize damage to the substrate 40 or the inorganic light-emitting elements 50 by ESD.

Although specific embodiments have been shown and described, however, the disclosure is not limited to these embodiments. It should be interpreted that various modifications may be made by one of ordinary skill in the technical art to which the disclosure belongs, without deviating from the gist of the technical concept of the disclosure, which is defined in the following claims.

What is claimed is:

1. A display apparatus comprising:
a display module array comprising a plurality of display modules arranged in a matrix,
wherein each display module of the plurality of display modules comprises:
a substrate comprising a mounting surface and a rear surface opposite to the mounting surface;
a plurality of inorganic light-emitting elements mounted on the mounting surface of the substrate;
a metal plate adhered to the rear surface of the substrate and configured to dissipate heat generated by the substrate;
a front cover covering the mounting surface;
a first conductive layer on the mounting surface; and
a second conductive layer between the front cover and the first conductive layer.

2. The display apparatus of claim 1, wherein each display module of the plurality of display modules further comprises an adhesive layer between the first conductive layer and the second conductive layer.

3. The display apparatus of claim 2, wherein the adhesive layer comprises a nonconductor.

4. The display apparatus of claim 3, wherein each display module of the plurality of display modules further comprises an optical sheet between the front cover and the second conductive layer.

5. The display apparatus of claim 4, wherein the second conductive layer is grounded to outside of each display module of the plurality of display modules.

6. The display apparatus of claim 4, wherein the second conductive layer is exposed to outside of each display module of the plurality of display modules.

7. The display apparatus of claim 5, wherein each display module of the plurality of display modules further comprises an insulating layer between the second conductive layer and the adhesive layer.

8. The display apparatus of claim 7, wherein each display module of the plurality of display modules further comprises a driving circuit board on the metal plate and configured to electrically control the plurality of inorganic light-emitting elements,
wherein the substrate further comprises:
a side surface;
a chamfer portion between the mounting surface and the side surface and between the rear surface and the side surface;
a side wiring extending along the side surface and the chamfer portion and electrically connecting the plurality of inorganic light-emitting elements to the driving circuit board, and
wherein the second conductive layer extends further in a side direction than the side wiring.

9. The display apparatus of claim 8, wherein the first conductive layer is an anisotropic conductive layer, and
wherein the second conductive layer comprises a transparent conductive oxide.

10. The display apparatus of claim 1, further comprising a frame configured to support the front cover,
wherein the second conductive layer of each display module of the plurality of display modules is positioned toward the front cover and spaced from the first conductive layer of the display module.

11. The display apparatus of claim 10, wherein each display module of the plurality of display modules further comprises an optical sheet between the front cover and the second conductive layer.

12. The display apparatus of claim 11, wherein the second conductive layer of each display module of the plurality of display modules is grounded to outside of the display module.

13. The display apparatus of claim 11, wherein the second conductive layer each display module of the plurality of display modules is exposed to outside of the display module.

14. A display module comprising:
a substrate comprising:
a mounting surface;
a rear surface opposite to the mounting surface; and
a side surface;
a plurality of inorganic light-emitting elements mounted on the mounting surface of the substrate;
a front cover covering the mounting surface and comprising a side end extending to an outer area from the mounting surface;
a side cover covering the side surface and adhered on a lower surface of the front cover corresponding to the outer area from the mounting surface and the side surface of the substrate;
a metal plate adhered on the rear surface and configured to dissipate heat generated by the substrate;
an adhesive layer between the substrate and the front cover and configured to adhere the front cover to the substrate; and
a conductive layer between the front cover and the adhesive layer.

15. The display module of claim 14, further comprising an anisotropic conductive layer on the mounting surface.

16. The display module of claim 14, further comprising an optical sheet between the front cover and the conductive layer.

17. The display module of claim 14, wherein the conductive layer is grounded to outside of the display module or exposed to the outside of the display module.

18. The display module of claim 14, wherein the conductive layer comprises a transparent conductive oxide.

19. A display module comprising:
a substrate comprising:
a mounting surface;
a rear surface opposite to the mounting surface; and
a side surface;
a plurality of inorganic light-emitting elements mounted on the mounting surface of the substrate;
a metal plate adhered on the rear surface;
a front cover covering the mounting surface;
an optical sheet between the substrate and the front cover;
an anisotropic conductive layer applied on the mounting surface;
a transparent conductive oxide between the optical sheet and the anisotropic conductive layer; and
an adhesive layer between the anisotropic conductive layer and the transparent conductive oxide and comprising a nonconductor.

20. The display module of claim 19, wherein the transparent conductive oxide is grounded to outside of the display module or exposed to the outside of the display module.
